(19) United States
(12) Patent Application Publication
(10) Pub. No.: US 2024/0411233 A1
(43) Pub. Date: Dec. 12, 2024

(54) LITHOGRAPHIC APPARATUS AND ASSOCIATED METHODS

(71) Applicant: ASML NETHERLANDS B.V., Veldhoven (NL)

(72) Inventors: Gosse Charles DE VRIES, Veldhoven (NL); Sjoerd Nicolaas Lambertus DONDERS, Vught (NL); Franciscus Johannes Joseph JANSSEN, Geldrop (NL); Evgenia KURGANOVA, Nijmegen (NL); Abraham Jan WOLF, Nuenen (NL); Ties Jan Willem BAKKER, Utrecht (NL); Volker Dirk HILDENBRAND, Eindhoven (NL); Paul Alexander VERMEULEN, Eindhoven (NL); Michael ENGEL, Eindhoven (NL); Bernardus Antonius Johannes LUTTIKHUIS, Breda (NL); Ronald VAN DER HAM, Maarheeze (NL); Jeroen Peterus Johannes VAN LIPZIG, Roermond (NL)

(73) Assignee: ASML NETHERLANDS B.V., Veldhoven (NL)

(21) Appl. No.: 18/699,358

(22) PCT Filed: Oct. 7, 2022
(86) PCT No.: PCT/EP2022/077938

§ 371 Date: Apr. 8, 2024

(30) Foreign Application Priority Data
Oct. 21, 2021 (EP) 21204036.4
Mar. 16, 2022 (EP) 22162403.4

(51) Int. Cl. G03F 7/00; G03F 1/62

(52) U.S. Cl. CPC G03F 7/70875; G03F 1/62; G03F 7/70033; G03F 7/70233; G03F 7/70716; G03F 7/70983

(57) ABSTRACT

A lithographic apparatus includes: an illumination system configured to condition a radiation beam; a support structure constructed to support a reticle and pellicle assembly for receipt of the radiation beam conditioned by the illumination system; a substrate table constructed to support a substrate; a projection system configured to receive the radiation beam from the reticle-pellicle assembly and to project it onto the substrate; and a heating system configured to heat a pellicle of the reticle-pellicle assembly supported by the support structure. A method for using a reticle-pellicle assembly including: illuminating the reticle-pellicle assembly with a radiation beam so as to form a patterned image on a substrate; and heating the pellicle of the reticle-pellicle assembly using a separate heat source.

### CROSS-REFERENCE TO RELATED APPLICATIONS

This application claims priority of EP application 212040364 which was filed on Oct. 21, 2021 and EP application 221624034 which was filed on Mar. 16, 2022 and which are incorporated herein in its entirety by reference.

### FIELD

The present invention relates to an apparatus and associated method for processing or using a reticle and pellicle assembly for use within an extreme ultraviolet (EUV) lithographic apparatus. The present invention also relates to a pellicle that may be particularly suitable for use in the apparatus and method for processing a reticle and pellicle assembly.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g., a mask) onto a layer of radiation-sensitive material (resist) provided on a substrate.

The wavelength of radiation used by a lithographic apparatus to project a pattern onto a substrate determines the minimum size of features that can be formed on that substrate. A lithographic apparatus that uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A patterning device (e.g., a mask) that is used to impart a pattern to a radiation beam in a lithographic apparatus may form part of a mask assembly. A mask assembly may include a pellicle that protects the patterning device from particle contamination. The pellicle may be supported by a pellicle frame.

It may be desirable to provide an apparatus that obviates or mitigates one or more problems associated with the prior art.

### SUMMARY

According to a first aspect of the disclosure there is provided a lithographic apparatus comprising: an illumination system configured to condition a radiation beam; a support structure constructed to support a reticle and pellicle assembly for receipt of the radiation beam conditioned by the illumination system; a substrate table constructed to support a substrate; and a projection system configured to receive the radiation beam from the reticle and pellicle assembly and to project said radiation beam onto the substrate, wherein the lithographic apparatus further comprises: a heating system operable to heat a pellicle of the reticle and pellicle assembly supported by the support structure.

The lithographic apparatus according to the first aspect is advantageous, as now discussed.

It will be appreciated that the reticle is configured to impart the radiation beam received from the illumination system with a pattern in its cross-section to form a patterned radiation beam. The projection system forms a (diffraction-limited) image of the reticle on the substrate. Any contamination on the reticle will, in general, alter the image formed on the substrate, leading to printing errors.

The lithographic apparatus may be an extreme ultraviolet (EUV) lithographic apparatus. To avoid particle contamination of the reticles, it is known to use a thin membranes, known as a pellicle, to protect the reticle. The pellicle is disposed in front of the reticle prevents particles from the landing on the reticle. The pellicle is disposed such that it is not sharply imaged by the projection system and therefore particles on the pellicle do not interfere with the imaging process. One particularly promising material for use as a pellicle membrane in an EUV lithographic apparatus is a fabric of carbon nanotubes (CNTs), which can provide very high EUV transmission (of >98%) and a very good mechanical stability. However, a low pressure hydrogen gas is typically provided within the lithographic apparatus, which forms a hydrogen plasma in the presence of the EUV radiation (during exposure). It has been found that this hydrogen ions and hydrogen free radicals from the hydrogen plasma can etch pellicles formed from CNTs, limiting the potential lifetime of the pellicle and blocking commercial implementation of CNT pellicles.

The inventors of the present invention have realized that the etching of carbon by hydrogen ions and free radicals is temperature dependent. In particular, the inventors have realized that (a) the carbon etching rate is non-zero at lower temperatures; (b) the carbon etching rate falls to a negligible level at a threshold temperature, above which the carbon etching remains at a negligible level; and (c) that a pellicle within an EUV lithographic scanner will typically cycle through a range of temperatures sampling temperatures at which the carbon etching rate is not negligible during each cycle. For example, in an EUV lithographic scanner, during operation, an EUV radiation beam scans back and forth over the pellicle, which leads to permanent temperature fluctuations. If the temperature of the pellicle is below the threshold temperature at which the carbon etching rate falls to a negligible level, even for part of the time during the scanning exposure, then the pellicle will degrade rapidly. Depending on various factors, it may be that there is a peak in the carbon etching rate at a temperature below the threshold temperature. If present, the peak in the carbon etching rate may be, for example, at a temperature between 600 K and 800 K. Furthermore, the fluctuations may be such that the temperature of the pellicle repeatedly crosses this peak, leading to enhanced degradation and a reduced lifetime of CNT pellicles. If the temperature of the pellicle during exposure of the reticle is maintained at a sufficiently high temperature then the rate of degradation can be maintained at low level and the pellicle lifetime is dramatically extended. As explained further below, the value above which it is desired to maintain the temperature of the pellicle may depend on various factors. It may be desirable to maintain the pellicle above the threshold temperature although it will be appreciated that even by maintaining the pellicle at a temperature which is close to by slightly below the threshold temperature may significantly reduce the rate of degradation of the pellicle. Furthermore, as also explained further below, the value of the threshold temperature may also depend on various factors. For example, it may be desirable to maintain the temperature of the pellicle permanently above 600, or more preferably above 700 K, or more preferably above 800 K. It is expected that by maintaining the temperature of the pellicle at a suitable temperature the rate of degradation can be reduced by at least an order of magnitude, dramatically extending the lifetime of the pellicle.

Advantageously, by providing a heating system arranged to heat a pellicle of the reticle and pellicle assembly supported by the support structure, the lithographic apparatus according to the first aspect can ensure that the temperature of the pellicle, or at least any parts of the pellicle which are adjacent the hydrogen plasma, can be maintained at a safe temperature (for example, above the threshold temperature at which the carbon etching rate is at a negligible level). It will be appreciated that the heating system provides a mechanism to provide heat to the pellicle that is in addition to the heating provided by the radiation beam from the illumination system.

The lithographic apparatus may further comprise a controller operable to control the heating system so as to heat a pellicle of the reticle and pellicle assembly supported by the support structure so as to achieve a target temperature distribution.

During exposure of a reticle and pellicle assembly supported by the support structure to radiation from the illumination system, the heating system may be configured to maintain at least a portion of the pellicle of said reticle and pellicle assembly above a minimum temperature.

The minimum temperature may be at or above the threshold temperature above which a hydrogen etching rate of the pellicle falls to a negligible level. It will be appreciated that the hydrogen etching rate of a pellicle within a lithographic apparatus is dependent on a number of factors such as, for example: a material from which the pellicle is formed; a flux of hydrogen ions incident on the pellicle; an energy distribution of ions that are incident on the pellicle.

As will be appreciated by the skilled person, within a lithographic apparatus, the hydrogen plasma is formed by the EUV radiation (used for exposure of the substrate). Therefore, at any given time, the at least a portion of the pellicle of said reticle and pellicle assembly which is maintained above a minimum temperature may comprise a portion of the pellicle that receives the EUV radiation from the illumination system. It will be further appreciated that the plasma may extend to surrounding regions. Therefore, at any given time, the at least a portion of the pellicle of said reticle and pellicle assembly which is maintained above a minimum temperature may comprise a portion of the pellicle that is centered on, but is slightly larger than, the portion of the pellicle that is receiving the EUV radiation from the illumination system.

For example, in some embodiments, the lithographic apparatus may be provided with a pellicle formed from CNTs.

The interaction of hydrogen ions with carbon materials is described quantitatively in the following two published papers, the contents of which are hereby incorporated by reference: (1) J. Roth, C. García-Rosales, “Analytic description of the chemical erosion of graphite by hydrogen ions”, Nucl. Fusion 1996, 36/12, 1647-1659; and (2) J. Roth, C. García-Rosales, “Corrigendum-Analytic description of the chemical erosion of graphite by hydrogen ions”, Nucl. Fusion 1997, 37, 897. This quantitative description of the interaction of hydrogen ions with carbon materials may be referred to as Roth-García-Rosales (RGR) model. The RGR model can be used to predict an etch yield of carbon materials as function of the temperature for the typical hydrogen ion energies encountered within the lithographic apparatus such as, for example, ion energies form 1-30 eV. Within an EUV lithographic apparatus a typical hydrogen ion flux incident on the pellicle may be of the order of 1·10¹⁹ m⁻²·s⁻¹. Within an EUV lithographic apparatus a typical hydrogen ion flux incident on the pellicle may be within a couple of orders of magnitude of 1·10¹⁹ m⁻²·s⁻¹ (for example from 10¹⁸ m⁻²·s⁻¹ to 10²⁰ m⁻²·s⁻¹).

For these typical ambient conditions, it is expected that for a pellicle formed purely from CNTs the hydrogen etching rate of the pellicle falls to a negligible level at a temperature of around 1050 K. However, it will be appreciated by the skilled person that under different conditions a different minimum temperature may be desirable.

The minimum temperature may be a temperature at which a hydrogen etching rate of the pellicle is negligible.

The minimum temperature may be 600 K or above.

The minimum temperature may be 700 K or above.

The minimum temperature may be 800 K or above.

The minimum temperature may be 900 K or above.

The minimum temperature may be 1000 K or above.

As explained above, this may be beneficial for a pellicle formed purely from CNTs wherein there is hydrogen ion flux incident on the pellicle may be of the order of 1·10¹⁹ m⁻²·s⁻¹ and the hydrogen ion energies are of the order of 1-30 eV.

More preferably, the minimum temperature may be 1050 K or above. In some embodiments, the minimum temperature may be 1100 K or above.

The inventors have further realized that the reduction of hydrogen etch rates to negligible levels at high temperatures is governed by the transformation of sp3 carbon into sp2 carbon at a given temperature. Furthermore, a similar process occurs when forming sp2 carbon structures such as graphene or CNTs, wherein a temperature of carbon is raised to transform it into sp2 carbon from which the sp2 carbon structures are formed. Such processes for growing graphene include, for example chemical vapor deposition (CVD) and plasma-enhanced chemical vapor deposition (PE-CVD). Furthermore, it is known that growth of graphene from sp3 carbon sources can be initiated at temperatures as low as 300° C. (573K) in the presence of single atoms catalyst. That is, conversion of sp3 carbon into sp2 carbon can be initiated at this temperature in the presence of single atoms catalyst. Lowering the etch-free operating temperature range for the pellicle is beneficial since it reduces the heat load to the environment of the pellicle. It also means that less heat has to be supplied to the pellicle, which may ease the systems providing this heat.

Therefore, it is proposed by the inventors of the present invention that pellicles formed from CNTs should be provided with a concentration of additives which can act as a catalyst for conversion of sp3 carbon into sp2 carbon. As a result, it is expected that the threshold temperature above which a hydrogen etching rate of the pellicle falls to a negligible level can be reduced from ˜1050K for pure CNT pellicles to, for example, of the order of 573K. It will be appreciated by the skilled person that the actual threshold temperature will be dependent on the material and concentration of the additives.

It is proposed to add transitional metal atoms to the CNT pellicles, such as, for example, molybdenum (Mo), chromium (Cr), nickel (Ni), copper (Cu), iron (Fe). Furthermore, it is expected by the inventors of the present invention that a relatively low concentration of such catalyst atoms, for example of the order of 0.1-1% with respect to carbon atoms may be sufficient. Such concentrations are not expected to have a significant impact on the transmission of EUV radiation through the pellicle.

The heating system may be configured to heat at least a portion of the pellicle surrounding the portion of the pellicle which is currently receiving the radiation beam.

It may be particularly beneficial to heat the portion of the pellicle surrounding the portion of the pellicle which is currently receiving the radiation beam since the hydrogen plasma may extend over said portion of the pellicle but that portion of the pellicle is not receiving heat from the radiation beam (rather it will be radiating this heat and cooling rapidly).

The lithographic apparatus may further comprise a support structure scanning mechanism operable to move the support structure relative to the radiation beam conditioned by the illumination system so as to move a reticle and pellicle assembly supported by the support structure through said radiation beam. The heating system may be configured to heat at least a portion of the pellicle which is currently receiving the radiation beam.

That is, the exposure of the substrate is performed as a scanning exposure. It will be appreciated that a corresponding scanning mechanism is arranged to synchronously scan the substrate table (and any substrate supported thereby) through the radiation beam received from the projection system.

As will be appreciated by the skilled person, within a lithographic apparatus, the hydrogen plasma is formed by the EUV radiation (used for exposure of the substrate). Therefore, at any given time, the at least a portion of the pellicle of said reticle and pellicle assembly which is maintained above a minimum temperature may comprise a portion of the pellicle that receives the EUV radiation from the illumination system.

Projected onto a plane of the reticle and/or pellicle the radiation beam may form an elongate band of radiation which may be referred to as the exposure slit, or the slit.

Heating the pellicle in the slit may be advantageous since in existing lithographic apparatus there may be line-of-sight towards the slit from the illumination system and/or from the projection system. This may allow the heating system to irradiate the pellicle with electromagnetic radiation so as to heat the pellicle.

The heating system may be configured to heat at least a portion of the pellicle surrounding the portion of the pellicle which is currently receiving the radiation beam.

It will be further appreciated that the plasma may extend to surrounding regions.

Therefore, at any given time, the at least a portion of the pellicle of said reticle and pellicle assembly which is maintained above a minimum temperature may comprise a portion of the pellicle that is centered on, but is slightly larger than, the portion of the pellicle that is receiving the EUV radiation from the illumination system.

The heating system may be configured so as to heat a pellicle of the reticle and pellicle assembly supported by the support structure so that a combined heat load from the heating system and the radiation beam received from the illumination system achieves a target temperature distribution.

For example, the heating system may be configured such that the entire pellicle is maintained at a desired temperature or temperature range (for example greater than 1050 K).

The heating system may be configured to heat substantially an entire membrane of the pellicle.

A potential problem of the only heating the region of the slit may be an insufficient suppression of the etching just outside the slit. Although the hydrogen ion flux will rapidly decrease at pellicle locations outside the radiation slit, it may be that the combination of still having some ion flux and insufficient pellicle temperature will lead to some etching that affects life time of the pellicle in a negative way.

The heating system may comprise a radiation source operable to direct radiation at the pellicle of a reticle and pellicle assembly when supported by the support structure.

The radiation source may be operable to direct electromagnetic radiation at the pellicle.

The radiation source may be operable to direct electrons so as to be incident on the pellicle of a pellicle of a reticle and pellicle assembly when supported by the support structure. The radiation source may comprise an electron gun.

The lithographic apparatus may further comprise electron optics arranged to receive an electron beam from an electron source and to distribute the electron beam over a surface of the pellicle of a reticle and pellicle assembly when supported by the support.

The lithographic apparatus may further comprise a heating scanning mechanism operable to move at least one of the radiation source and the support structure such that radiation emitted by the radiation source can be directed at a range of different parts of a pellicle of a reticle and pellicle assembly when supported by the support structure.

It will be appreciated that the heating scanning mechanism may be operable to account for both: (a) movement of the pellicle (due to movement of the support structure); and (b) movement of the radiation relative to the pellicle (whether static or moving with the support structure).

The heating system may be arranged to supply an electrical current through the pellicle of a pellicle and reticle assembly when supported by the support structure.

That is, the heating system may be arranged to heat the pellicle using Joule heating or electrical heating. Such embodiments using the electrical resistivity of the pellicle itself to heat the pellicle.

The heating system may comprise a plurality of electrodes operable to contact different parts of the pellicle of the reticle and pellicle assembly and a power supply arranged to provide voltages across at least two of the plurality of electrodes.

For example, two strip-like electrodes may be provided along two opposed sides of the pellicle and a voltage may be provided across the two electrodes. With such an arrangement, a current will flows between (and generally perpendicular to) the two electrodes from one of the opposed side of the pellicle to the other.

More complicated heating profiles can be applied, by using more electrodes and suitable voltage levels at these electrodes. Modulation of the voltages in time is also conceivable to obtain in principle any heat profile that is beneficial.

The heating system may comprise: an electrode; and a voltage supply operable to apply a voltage across the electrode and at least a portion of the pellicle of a reticle and pellicle assembly when supported by the support structure.

Advantageously, such an arrangement allows for thermionic heating of the pellicle. In use, the voltage supply may be such that the electrode can act as a cathode and the at least a portion of the pellicle can act as an anode. With such an arrangement electrons that are emitted by the cathode are directed towards the at least a portion of the pellicle. The electrons are attracted to the (positively charged) at least a portion of the pellicle and are not attracted to other parts of the lithographic apparatus. Therefore, one advantage of such thermionic heating is that the heating is targeted such that there is no or minimal heating of other parts of the lithographic apparatus. Another advantage of such thermionic heating is that the high heat transfers can be achieved.

In some embodiments, the voltage supply may be operable to apply a voltage across the electrode and the whole pellicle of a reticle and pellicle assembly when supported by the support structure. For example, the pellicle may comprise a continuous conducting layer and the voltage supply may be configured to apply a voltage to the conductive layer. In other embodiments, the voltage supply may be operable to apply a voltage across the electrode and one of a plurality of parts of the pellicle of a reticle and pellicle assembly when supported by the support structure. For example, the pellicle may comprise a broken conducting layer comprising a plurality of separate conducting portions and the voltage supply may be configured to apply a voltage to one or more of the plurality of conductive portions.

The heating system may further comprise: a heater operable to heat the electrode.

In use, the heater may be operable to maintain the temperature of the electrode at a suitable temperature such that a thermal energy of electrons in the electrode exceeds the work function of the material from which the electrode is formed.

In embodiments comprising a controller, the controller may be operable to control the voltage applied by the voltage supply.

In some embodiments, the heating system may be operable to periodically heat the pellicle of the reticle and pellicle assembly supported by the support structure.

In some embodiments, the heating system may be operable to provide pulsed heating to the pellicle of the reticle and pellicle assembly supported by the support structure.

As discussed above, some pellicles, in particular those formed from carbon nanotubes (CNTs), are susceptible to hydrogen plasma etching within the lithographic apparatus LA. It is expected that there is a threshold temperature above which a hydrogen etching rate of the CNT pellicle 19 falls to a negligible level. This temperature threshold is dependent on a number of factors but it may be of the order of 700° C. Therefore, as this etching process can be strongly suppressed by heating the CNT pellicle 19 continuously to over 700° C.

It will be appreciated that such periodic or pulsed heating will result in a periodically varying or pulsed temperature profile of the pellicle. However, the inventors have realized that once the pellicle has been heated to above the threshold level, once the heating is removed, there is a time delay before the etching rate increases from the negligible level. It is thought that heating to a sufficient temperature causes desorption of hydrogen from the pellicle, which reduces the hydrogen etching rate to negligible levels. Furthermore, it is thought that there is a time delay in the increase in the etching rate after removal of the heating as it takes a non-zero time for the surfaces of the pellicle to be replenished with hydrogen following the heating.

Advantageously, by only periodically heat the pellicle of the reticle and pellicle assembly and/or by providing pulsed heating to the pellicle of the reticle and pellicle assembly the power supplied by the heating system is significantly reduced relative, for example, to an arrangement wherein the pellicle is continuously heated. This reduces the additional heating load from the heating system provided in the vicinity of the reticle and pellicle assembly when supported by the support structure. In turn, this reduces the amount of power needed for the heating system and the amount of cooling capacity that is needed to absorb the heat load. It also reduces the additional heat load to the reticle which can cause distortion of the reticle and may impact imaging performance of the lithographic apparatus (for example such heat loads may contribute to overlay).

Furthermore, by only periodically heating the pellicle of the reticle and pellicle assembly and/or by providing pulsed heating to the pellicle of the reticle and pellicle assembly, the heating system may operate in between exposures in the lithographic apparatus. For example, the heating system may operate in between exposures of different target regions (or dies) of a single substrate or even in between exposures of different substrates. In turn, by allowing for heating in between exposures, the heating system may be located differently to an arrangement wherein it is desirable to heat the pellicle during exposure of a substrate. Advantageously, this may make integration of the heating system into the lithographic apparatus easier as there may be more space to accommodate the heating system in a location that, for example, can heat the pellicle when the support structure is in a non-exposure position or location.

In general, a duration of the heating pulse may be sufficiently large to heat the pellicle to a desired temperature (for example above a threshold temperature above which hydrogen etching of the pellicle is negligible). For example, the duration of the heating pulse can range from 0.1 ms to 100 ms, more preferably from 1 to 10 ms. It will be appreciated that the time required for heating the pellicle to a desired temperature will be dependent on a power of the heating system while it is heating the pellicle. In some embodiments, a duration of the heating pulse may be of the order of 1 ms.

In general, a time period between two consecutive heating pulses may be sufficiently small so as to not allow a surface of the pellicle to become replenished with hydrogen following the heating from the first pulse. Again, it will be appreciated that the time required for the surface of the pellicle to become replenished with hydrogen following the heating from the first pulse will be dependent on conditions in the vicinity of the pellicle. Taking into account some variability in radical flux in a high power lithographic apparatus it has been determined that the time that may be needed in between heating pulses may range from two dies (back and forth) to an entire wafer exposure. In terms of time in between heating pulses this is in a range from 50 ms to 20 seconds, more preferably from 100 ms to 10 seconds. In some embodiments, a time period between two consecutive heating pulses may be of the order of 100 ms.

It is thought that within an EUV lithographic apparatus, the hydrogen etching can be maintained at an acceptable or negligible level by providing periodic or pulsed heating for a very small fraction of the time. Therefore, in some embodiments, the heating of the pellicle of the reticle and pellicle assembly supported by the support structure provided by the heating system comprises a relatively low duty cycle pulsed heating, as now discussed.

A duty cycle of the heating system may be 0.1 or less. The duty cycle may be a ratio of: a fraction of time during which the heating system provides heating to the pellicle; to a fraction of time during which the heating system provides no heating to the pellicle.

Advantageously, such an arrangement would reduce the amount of power provided by the heating system by a factor of 10 relative to an arrangement wherein the pellicle is heated continuously. A duty cycle of the heating system of 0.1 or less is thought to be sufficient to maintain the hydrogen etching of the pellicle at an acceptable or negligible level even for the worst case scenario for conditions within an EUV lithographic apparatus.

However, it is thought that in practice even smaller duty cycles will be sufficient to maintain the hydrogen etching of the pellicle at an acceptable or negligible level. For example, in some embodiments, the duty cycle of the heating system may be 0.01 or less. In some embodiments, the duty cycle of the heating system may be 10⁻³ or less. In some embodiments, the duty cycle of the heating system may be 10⁻⁴ or less. In some embodiments, the duty cycle of the heating system may be 10⁻⁵ or less.

The lithographic apparatus may be operable to form an image of a reticle of the reticle and pellicle assembly supported by the support structure on a plurality of different target regions of a substrate supported by the substrate table. For such embodiments, the heating system may be operable to heat each part of the pellicle that is heated once per exposure of every n target regions, where n is an integer.

In some embodiments, n may be greater than 1. Also, the heating system may be operable to separately heat parts of the pellicle in the scanning direction (y-direction) versus the perpendicular direction (x-direction), since some of the pellicle regions may suffer more from plasma degradation than others.

By only heating each part of the pellicle that is heated once per exposure of every n target regions, the heating system may be located differently to an arrangement wherein the pellicle is continuously heated during exposure of a substrate. Advantageously, this makes integration of the heating system into the lithographic apparatus easier as there may be more space to accommodate the heating system in a location that, for example, can heat the pellicle when the support structure is in a non-exposure position or location.

In a scanning lithographic apparatus, during exposure of one target region of a substrate the support substrate is moved (or scanned) through the path of the radiation beam conditioned by the illumination system from a first end position (on one side of the radiation beam) to a second end position (on the other side of the radiation beam). Typically, for exposure of the next target region of the substrate the support substrate is moved back through the path of the radiation beam from the second end position to the first end position. Providing line of sight to the pellicle when it is being exposed to the radiation beam is challenging. However, there is typically more space to provide heating to the pellicle when the support structure is disposed in one of the first or second end positions.

The heating system may be operable to heat each part of the pellicle that is heated once per exposure of every 4 target regions.

Heating the pellicle after exposure of every 4 dies is thought to be sufficient to maintain the hydrogen etching of the pellicle at an acceptable or negligible level even for the worst case scenario for conditions within an EUV lithographic apparatus.

However, it is thought that in practice less frequent heating will be sufficient to maintain the hydrogen etching of the pellicle at an acceptable or negligible level. For example, in some embodiments, the heating system may be operable to heat each part of the pellicle that is heated once per exposure of every 10 target regions. In some embodiments, the heating system may be operable to heat each part of the pellicle that is heated once per exposure of every 100 target regions. In some embodiments, the heating system may be operable to heat each part of the pellicle that is heated once per exposure of every 1000 target regions.

The heating system may be operable to heat the pellicle in a time between: the formation of an image of the reticle on one target region of the substrate; and the formation of an image of the reticle on the next target region of the substrate.

The heating system may be operable to heat the pellicle of the reticle and pellicle assembly supported by the support structure in between exposure of one substrate and a subsequent substrate.

The heating system may be configured to heat a portion of the pellicle which is not currently receiving the radiation beam.

The lithographic apparatus may further comprise a support structure scanning mechanism operable to move the support structure relative to the radiation beam conditioned by the illumination system so as to move a reticle and pellicle assembly supported by the support structure through said radiation beam and the heating system may be configured to heat a portion of the pellicle which is not currently receiving the radiation beam as the reticle and pellicle assembly supported by the support structure is moved through said radiation beam.

In such embodiments, the heating system uses the movement of the support structure that scans the reticle through the EUV radiation beam to also scan the pellicle through a heating beam.

The heating system may be configured to heat substantially an entire membrane of the pellicle.

Alternatively, in some embodiments the heating system may be configured to heat a portion of the pellicle that does not, in use, receive the radiation beam conditioned by the illumination system.

The periodic heating from the EUV may be sufficient to suppress hydrogen etching of a portion of the pellicle that does, in use, receive the radiation beam conditioned by the illumination system. Therefore, in some embodiments, the heating system may only heat portion of the pellicle that does not, in use, receive the radiation beam conditioned by the illumination system.

The heating system may be configured to maintain at least a portion of the pellicle of said reticle and pellicle assembly above a minimum temperature. The minimum temperature may be a temperature at which a hydrogen etching rate of the pellicle is negligible. The minimum temperature may be 700° C. or above. The minimum temperature may be 750° C. or above. The minimum temperature may be 800° C. or above.

The lithographic apparatus may further comprise a temperature sensor operable to determine a temperature of at least a portion of the pellicle of a pellicle and reticle assemble supported by the support structure.

The temperature sensor may be operable to determine a temperature profile of at least a portion of the pellicle of a pellicle and reticle assemble supported by the support structure.

The heating system may be operable to heat the pellicle of the reticle and pellicle assembly supported by the support structure in dependence on a determined temperature or temperature profile of at least a portion of the pellicle.

That is, the heating system and the temperature sensor may form part of a feedback loop.

The lithographic apparatus may further comprise a hydrogen supply operable to supply hydrogen in the vicinity of the pellicle of the pellicle and reticle assembly when supported by the support structure.

According to a second aspect of the disclosure there is provided a method for using a reticle and pellicle assembly, the method comprising: illuminating the reticle and pellicle assembly with a radiation beam so as to impart the radiation beam with a pattern in its cross-section and forming an image of the reticle on a substrate; and heating the pellicle of the reticle and pellicle assembly using a separate heat source.

The method according to the second aspect is advantageous, as now discussed.

It will be appreciated that the method may form part of an EUV lithographic process. It will be further appreciated that as the reticle and pellicle assembly is illuminated with the radiation beam, a portion of the radiation will be absorbed by the pellicle, heating the pellicle. Advantageously, by heating the pellicle using a separate heat source, the method according to the second aspect can ensure that the temperature of the pellicle, or at least any parts of the pellicle which, in use, are adjacent a hydrogen plasma, can be maintained at a safe temperature at which the carbon etching rate is at a negligible level.

The heating of the pellicle of the reticle and pellicle assembly using a separate heat source may be such that the pellicle achieves a target temperature distribution.

The heating of the pellicle of the reticle and pellicle assembly using a separate heat source may be such that at least a portion of the pellicle of said reticle and pellicle assembly is maintained above a minimum temperature.

The heating of the pellicle of the reticle and pellicle assembly using a separate heat source may be such that a temperature of the pellicle is sufficiently large that a hydrogen etching rate of the pellicle is at a negligible level.

The heating of the pellicle of the reticle and pellicle assembly using a separate heat source may be such that a temperature of the pellicle is 600 K or above.

The heating of the pellicle of the reticle and pellicle assembly using a separate heat source may be such that a temperature of the pellicle is 700 K or above.

The heating of the pellicle of the reticle and pellicle assembly using a separate heat source may be such that a temperature of the pellicle is 800 K or above.

The heating of the pellicle of the reticle and pellicle assembly using a separate heat source may be such that a temperature of the pellicle is 900 K or above.

The heating of the pellicle of the reticle and pellicle assembly using a separate heat source may be such that a temperature of the pellicle is 1000 K or above.

More preferably, the temperature of the pellicle may be 1050 K or above. In some embodiments, the temperature of the pellicle may be 1100 K or above.

During illumination of the reticle and pellicle assembly with the radiation beam the reticle and pellicle assembly may be moved through said radiation beam and at least a portion of the pellicle which is currently receiving the radiation beam may be heated using the separate heat source.

At least a portion of the pellicle surrounding the portion of the pellicle which is currently receiving the radiation beam may be heated using the separate heat source.

The heating of the pellicle using the separate heat source may be such that a combined heat load from the separate heat source and the radiation beam achieves a target temperature distribution.

Substantially an entire membrane of the pellicle may be heated using the separate heat source.

The heating of the pellicle using the separate heat source may comprise directing radiation at the pellicle.

For example, the radiation may comprise electromagnetic radiation and/or electrons.

The heating of the pellicle using the separate heat source by directing radiation at the pellicle may comprise scanning the radiation over the pellicle.

The heating of the pellicle using the separate heat source may comprise supplying an electrical current through the pellicle.

Heating the pellicle using the separate heat source may comprise: appling a positive voltage to at least a portion of the pellicle; and emitting electrons from an electrode in the vicinity of the pellicle.

That is, the heating the pellicle using the separate heat source is achieved using thermionic heating of the pellicle. Appling a positive voltage to the at least a portion of the pellicle may be achieved by applying a voltage across the at least a portion of the pellicle and the electrode. With such an arrangement, the electrode can act as a cathode and the at least a portion of the pellicle can act as an anode. With such an arrangement electrons that are emitted by the electrode are directed towards the at least a portion of the pellicle. The electrons are attracted to the (positively charged) at least a portion of the pellicle and are not attracted to other parts of the lithographic apparatus. Therefore, one advantage of such thermionic heating is that the heating is targeted such that there is no or minimal heating of other parts of the lithographic apparatus. Another advantage of such thermionic heating is that the high heat transfers can be achieved.

Emitting electrons from the electrode in the vicinity of the pellicle may comprise heating the electrode.

For example, the heating of the electrode may ensure that the temperature of the electrode is such that a thermal energy of electrons in the electrode exceeds the work function of the material from which the electrode is formed.

Heating the pellicle of the reticle and pellicle assembly using a separate heat source may comprise periodically heating the pellicle of the reticle and pellicle assembly using the separate heat source.

Heating the pellicle of the reticle and pellicle assembly using a separate heat source may comprise providing pulsed heating to the pellicle of the reticle and pellicle assembly.

As discussed above, some pellicles, in particular those formed from carbon nanotubes (CNTs), are susceptible to hydrogen plasma etching within the lithographic apparatus LA. It is expected that there is a threshold temperature above which a hydrogen etching rate of the CNT pellicle 19 falls to a negligible level. This temperature threshold is dependent on a number of factors but it may be of the order of 700° C. Therefore, as this etching process can be strongly suppressed by heating the CNT pellicle 19 continuously to over 700° C.

It will be appreciated that such periodic or pulsed heating will result in a periodically varying or pulsed temperature profile of the pellicle. However, the inventors have realized that once the pellicle has been heated to above the threshold level, once the heating is removed, there is a time delay before the etching rate increases from the negligible level. It is thought that heating to a sufficient temperature causes desorption of hydrogen from the pellicle, which reduces the hydrogen etching rate to negligible levels. Furthermore, it is thought that there is a time delay in the increase in the etching rate after removal of the heating as it takes a non-zero time for the surfaces of the pellicle to be replenished with hydrogen following the heating.

Advantageously, by only periodically heat the pellicle of the reticle and pellicle assembly and/or by providing pulsed heating to the pellicle of the reticle and pellicle assembly the power supplied by the heating system is significantly reduced relative, for example, to an arrangement wherein the pellicle is continuously heated. This reduces the additional heating load from the heating system provided in the vicinity of the reticle and pellicle assembly when supported by the support structure. In turn, this reduces the amount of power needed for the heating system and the amount of cooling capacity that is needed to absorb the heat load. It also reduces the additional heat load to the reticle which can cause distortion of the reticle and may impact imaging performance of the lithographic apparatus (for example such heat loads may contribute to overlay).

Furthermore, by only periodically heating the pellicle of the reticle and pellicle assembly and/or by providing pulsed heating to the pellicle of the reticle and pellicle assembly, the heating system may operate in between exposures in the lithographic apparatus. For example, the heating system may operate in between exposures of different target regions (or dies) of a single substrate or even in between exposures of different substrates. In turn, by allowing for heating in between exposures, the heating system may be located differently to an arrangement wherein it is desirable to heat the pellicle during exposure of a substrate. Advantageously, this may make integration of the heating system into the lithographic apparatus easier as there may be more space to accommodate the heating system in a location that, for example, can heat the pellicle when the support structure is in a non-exposure position or location.

In general, a duration of the heating pulse may be sufficiently large to heat the pellicle to a desired temperature (for example above a threshold temperature above which hydrogen etching of the pellicle is negligible). For example, the duration of the heating pulse can range from 0.1 ms to 100 ms, more preferably from 1 to 10 ms. It will be appreciated that the time required for heating the pellicle to a desired temperature will be dependent on a power of the heating system while it is heating the pellicle. In some embodiments, a duration of the heating pulse may be of the order of 1 ms.

In general, a time period between two consecutive heating pulses may be sufficiently small so as to not allow a surface of the pellicle to become replenished with hydrogen following the heating from the first pulse. Again, it will be appreciated that the time required for the surface of the pellicle to become replenished with hydrogen following the heating from the first pulse will be dependent on conditions in the vicinity of the pellicle. Taking into account some variability in radical flux in a high power lithographic apparatus it has been determined that the time that may be needed in between heating pulses may range from two dies (back and forth) to an entire wafer exposure. In terms of time in between heating pulses this is in a range from 50 ms to 20 seconds, more preferably from 100 ms to 10 seconds. In some embodiments, a time period between two consecutive heating pulses may be of the order of 100 ms.

It is thought that within an EUV lithographic apparatus, the hydrogen etching can be maintained at an acceptable or negligible level by providing periodic or pulsed heating for a very small fraction of the time. Therefore, in some embodiments, the heating of the pellicle of the reticle and pellicle assembly supported by the support structure provided by the heating system comprises a relatively low duty cycle pulsed heating, as now discussed.

A duty cycle of the heating of the pellicle may be 0.1 or less. The duty cycle may be a ratio of: a fraction of time during which heating is provided to the pellicle; to a fraction of time during which no heating is provided to the pellicle.

Advantageously, such an arrangement would reduce the amount of power provided by the heating system by a factor of 10 relative to an arrangement wherein the pellicle is heated continuously. A duty cycle of the heating system of 0.1 or less is thought to be sufficient to maintain the hydrogen etching of the pellicle at an acceptable or negligible level even for the worst case scenario for conditions within an EUV lithographic apparatus.

However, it is thought that in practice even smaller duty cycles will be sufficient to maintain the hydrogen etching of the pellicle at an acceptable or negligible level. For example, in some embodiments, the duty cycle of the heating system may be 0.01 or less. In some embodiments, the duty cycle of the heating system may be 10³ or less. In some embodiments, the duty cycle of the heating system may be 10⁻⁴ or less. In some embodiments, the duty cycle of the heating system may be 10⁻⁵ or less.

In some embodiments an image of the reticle may be formed on a plurality of different target regions of the substrate. For such embodiments, each part of the pellicle that is heated may be heated once per exposure of every n target regions, where n is an integer.

In some embodiments, n may be greater than 1.

By only heating each part of the pellicle that is heated once per exposure of every n target regions, the heating system may be located differently to an arrangement wherein the pellicle is continuously heated during exposure of a substrate. Advantageously, this makes integration of the heating system into the lithographic apparatus easier as there may be more space to accommodate the heating system in a location that, for example, can heat the pellicle when the support structure is in a non-exposure position or location.

In a scanning lithographic apparatus, during exposure of one target region of a substrate the support substrate is moved (or scanned) through the path of the radiation beam conditioned by the illumination system from a first end position (on one side of the radiation beam) to a second end position (on the other side of the radiation beam). Typically, for exposure of the next target region of the substrate the support substrate is moved back through the path of the radiation beam from the second end position to the first end position. Providing line of sight to the pellicle when it is being exposed to the radiation beam is challenging. However, there is typically more space to provide heating to the pellicle when the support structure is disposed in one of the first or second end positions.

Each part of the pellicle that is heated may be heated once per exposure of every 4 target regions.

Heating the pellicle after exposure of every 4 dies is thought to be sufficient to maintain the hydrogen etching of the pellicle at an acceptable or negligible level even for the worst case scenario for conditions within an EUV lithographic apparatus.

However, it is thought that in practice less frequent heating will be sufficient to maintain the hydrogen etching of the pellicle at an acceptable or negligible level. For example, in some embodiments, the heating system may be operable to heat each part of the pellicle that is heated once per exposure of every 10 target regions. In some embodiments, the heating system may be operable to heat each part of the pellicle that is heated once per exposure of every 100 target regions. In some embodiments, the heating system may be operable to heat each part of the pellicle that is heated once per exposure of every 1000 target regions.

The pellicle may be heated in a time between: the formation of an image of the reticle on one target region of the substrate; and the formation of an image of the reticle on the next target region of the substrate.

The pellicle may be heated in between exposure of one substrate and a subsequent substrate.

Heating the pellicle may comprise heating a portion of the pellicle which is not currently receiving the radiation beam.

The image of the reticle may be formed on the substrate during a scanning exposure and heating the pellicle may comprise heating a portion of the pellicle which is not currently receiving the radiation beam during that scanning exposure. In such embodiments, the heating system uses the movement of the support structure that scans the reticle through the EUV radiation beam to also scan the pellicle through a heating beam.

Heating the pellicle may comprise heating substantially an entire membrane of the pellicle.

Alternatively, heating the pellicle may comprise heating a portion of the pellicle that is not, in use, illuminated by the radiation beam.

The periodic heating from the EUV may be sufficient to suppress hydrogen etching of a portion of the pellicle that does, in use, receive the radiation beam conditioned by the illumination system. Therefore, in some embodiments, the heating system may only heat portion of the pellicle that does not, in use, receive the radiation beam conditioned by the illumination system.

Heating the pellicle may comprise maintaining at least a portion of the pellicle above a minimum temperature.

The minimum temperature may be a temperature at which a hydrogen etching rate of the pellicle is negligible. The minimum temperature may be 700° C. or above. The minimum temperature may be 750° C. or above. The minimum temperature may be 800° C. or above.

The method may further comprise determining a temperature of at least a portion of the pellicle.

Determining a temperature of at least a portion of the pellicle may comprises determining a temperature profile of at least a portion of the pellicle.

The step of heating the pellicle using the separate heat source may be dependent on a determined temperature or temperature profile of at least a portion of the pellicle.

The method may be carried out using an apparatus according to the first aspect of the present disclosure.

According to a third aspect of the disclosure there is provided a pellicle for use in a lithographic apparatus, the pellicle comprising a substrate formed from carbon nanotubes; wherein the substrate further comprises at least one additive.

The at least one additive may comprise a plurality of catalyst atoms distributed over the substrate.

A concentration of the at least one additive with respect to carbon atoms may be of the order of 0.1-2%. For example, a concentration of the at least one impurity with respect to carbon atoms may be of the order of 0.1-1%. It is expected that such a concentration of additives will not significantly decrease EUV transmissivity of the pellicle. For example, for a 1% concentration of molybdenum atoms it is estimated that EUV transmissivity of the pellicle will decrease by <0.1%. Similarly, for a 1% concentration of nickel atoms it is estimated that EUV transmissivity of the pellicle will decrease by <0.5%.

A concentration and type of the at least one additive may be such that a threshold temperature above which a hydrogen etching rate of the pellicle is negligible is less than 900 K.

In some embodiments, a concentration and type of the at least one additive is such that a threshold temperature above which a hydrogen etching rate of the pellicle falls to a negligible level is less than 800 K. In some embodiments, a concentration and type of the at least one additive is such that a threshold temperature above which a hydrogen etching rate of the pellicle falls to a negligible level is less than 700 K. In some embodiments, a concentration and type of the at least one additive is such that a threshold temperature above which a hydrogen etching rate of the pellicle falls to a negligible level is less than 600 K.

The at least one additive may comprise a transition metal.

The at least one additive may comprise: molybdenum, chromium, nickel, copper and/or iron.

The at least one additive may comprise boron.

A concentration of the at least one additive with respect to carbon atoms may be of the order of 15 at. %.

The at least one additive may comprise amorphous carbon.

It will be appreciated that one or more aspects or features described above or referred to in the following description may be combined with one or more other aspects or features.

### BRIEF DESCRIPTION OF THE DRAWINGS

Embodiments of the invention will now be described, by way of example only, with reference to the accompanying schematic drawings, in which:

FIG. 1 is a schematic illustration of a lithographic system comprising a lithographic apparatus and a radiation source;

FIG. 2A is a schematic plan view of the support structure and patterning device shown in FIG. 1 disposed in a first end position;

FIG. 2B is a schematic plan view of the support structure and patterning device shown in FIG. 1 disposed in a second end position;

FIG. 3A is a schematic illustration of a first cross section through a patterning device on the support structure and reticle masking blades of the lithographic apparatus of FIG. 1;

FIG. 3B is a schematic illustration of a second cross section through a patterning device on the support structure and reticle masking blades of the lithographic apparatus of FIG. 1;

FIG. 4 is a plan view showing the y masking blades and the x masking blades (dotted lines) of the lithographic apparatus of FIG. 1 in a first configuration;

FIG. 5 shows an expected etching rate for hydrogen etching of carbon as a function of temperature for a hydrogen ion flux of 1.5·10¹⁹ m⁻²·s⁻¹ for four different ion energies: 5 eV, 10 eV, 20 eV and 30 eV; FIG. 5 also shows an sp3 carbon concentration as a function of temperature;

FIG. 6 is a schematic illustration of a first example embodiment of the heating system of the lithographic apparatus shown in FIG. 1;

FIG. 7 is a schematic illustration of a variant of the heating system shown in FIG. 6;

FIG. 8 is a schematic illustration of another example embodiment of the heating system of the lithographic apparatus shown in FIG. 1;

FIG. 9 is a graph showing an estimation of the heating power of thermionic (dashed line) and radiation (dotted line) heating of a pellicle as a function of the temperature of the radiator;

FIG. 10 is a schematic, qualitative graph of the hydrogen etch rate as a function of time following a period of heating to a temperature at which hydrogen etching becomes negligible, once the heating is removed;

FIG. 11 is a schematic plan view of the support structure and patterning device shown in FIG. 1 disposed in the first end position and also showing a portion of the patterning device that is closest to the slit region when the support structure is disposed in the first end position;

FIG. 12A is a schematic view of a first embodiment of the heating system of the lithographic apparatus shown in FIG. 1 that is operable to heat each part of the pellicle that is heated once per exposure of every n target regions of the substrate using a radiation source to generate a radiation curtain that the pellicle is scanned through during exposure of the substrate;

FIG. 12B is a schematic plan view of the pellicle and the radiation curtain generated by the embodiment of the heating system shown in FIG. 12A;

FIG. 13A is a schematic view of a second embodiment of the heating system of the lithographic apparatus shown in FIG. 1 that is operable to heat each part of the pellicle that is heated once per exposure of every n target regions of the substrate using a radiation source to generate a radiation curtain that the pellicle is scanned through during exposure of the substrate;

FIG. 13B is a schematic plan view of the pellicle and the radiation curtain generated by the embodiment of the heating system shown in FIG. 13A;

FIG. 14A is a schematic view of a third embodiment of the heating system of the lithographic apparatus shown in FIG. 1 that is operable to heat each part of the pellicle that is heated once per exposure of every n target regions of the substrate using a radiation source to generate a radiation curtain that the pellicle is scanned through during exposure of the substrate;

FIG. 14B is a schematic plan view of the pellicle and the radiation curtain generated by, and a beam dump of, the embodiment of the heating system shown in FIG. 14A;

FIG. 15A is a schematic view of a fourth embodiment of the heating system of the lithographic apparatus shown in FIG. 1 that is operable to heat each part of the pellicle that is heated once per exposure of every n target regions of the substrate using a radiation source to generate a radiation curtain that the pellicle is scanned through during exposure of the substrate;

FIG. 15B is a schematic plan view of the pellicle and the radiation curtain generated by, and a beam dump and a mirror of, the embodiment of the heating system shown in FIG. 15A;

FIG. 16A is a schematic view of a fifth embodiment of the heating system of the lithographic apparatus shown in FIG. 1 that is operable to heat each part of the pellicle that is heated once per exposure of every n target regions of the substrate using a radiation source to generate a radiation curtain that the pellicle is scanned through during exposure of the substrate;

FIG. 16B is a schematic plan view of the pellicle and the radiation curtain generated by the embodiment of the heating system shown in FIG. 16A;

FIG. 17A shows an arrangement, in the x-z plane, wherein a single radiation source is operable to generate an entire radiation curtain;

FIG. 17B shows an arrangement, in the x-z plane, wherein a plurality of radiation sources are each operable to generate a portion of the radiation curtain;

FIG. 18A is a schematic view of a sixth embodiment of the heating system of the lithographic apparatus shown in FIG. 1 that is operable to heat each part of the pellicle that is heated once per exposure of every n target regions of the substrate using a radiation source to generate a radiation curtain that the pellicle is scanned through during exposure of the substrate;

FIG. 18B is a schematic plan view of the pellicle and the radiation curtain generated by the embodiment of the heating system shown in FIG. 18A;

FIG. 19A is a schematic view of a seventh embodiment of the heating system of the lithographic apparatus shown in FIG. 1 that is operable to heat each part of the pellicle that is heated once per exposure of every n target regions of the substrate using a radiation source to generate a radiation curtain that the pellicle is scanned through during exposure of the substrate; and

FIG. 19B is a schematic plan view of the pellicle and the radiation curtain generated by the embodiment of the heating system shown in FIG. 19A.

### DETAILED DESCRIPTION

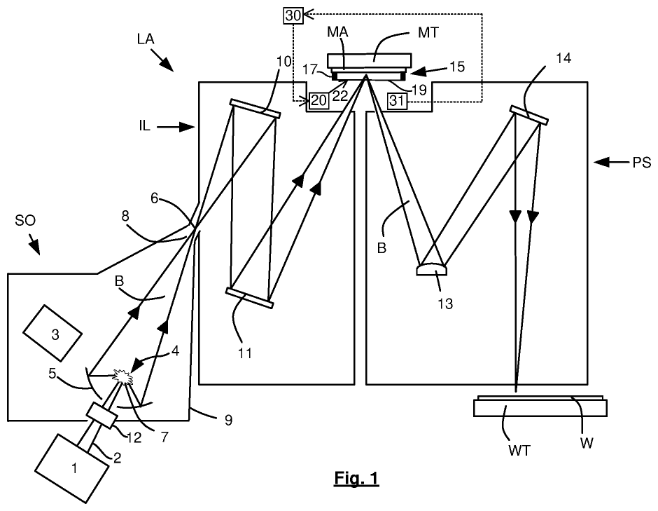

FIG. 1 shows a lithographic system. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a reticle assembly 15 including a patterning device MA (e.g., a reticle or mask), a projection system PS and a substrate table WT configured to support a substrate W. The illumination system IL is configured to condition the radiation beam B before it is incident upon the patterning device MA. The projection system is configured to project the radiation beam B (now patterned by the patterning device MA) onto the substrate W. The substrate W may include previously formed patterns. Where this is the case, the lithographic apparatus aligns the patterned radiation beam B with a pattern previously formed on the substrate W.

The radiation source SO, illumination system IL, and projection system PS may all be constructed and arranged such that they can be isolated from the external environment. A gas at a pressure below atmospheric pressure (e.g., hydrogen) may be provided in the radiation source SO. A vacuum may be provided in the illumination system IL and/or the projection system PS. A small amount of gas (e.g., hydrogen) at a pressure well below atmospheric pressure may be provided in the illumination system IL and/or the projection system PS.

The radiation source SO shown in FIG. 1 is of a type that may be referred to as a laser produced plasma (LPP) source. A laser 1, which may for example be a CO₂ laser, is arranged to deposit energy via a laser beam 2 into a fuel, such as tin (Sn) that is provided from a fuel emitter 3. Although tin is referred to in the following description, any suitable fuel may be used. The fuel may for example be in liquid form, and may for example be a metal or alloy. The fuel emitter 3 may comprise a nozzle configured to direct tin, e.g., in the form of droplets, along a trajectory towards a plasma formation region 4. The laser beam 2 is incident upon the tin at the plasma formation region 4. The deposition of laser energy into the tin creates a plasma 7 at the plasma formation region 4. Radiation, including EUV radiation, is emitted from the plasma 7 during de-excitation and recombination of ions of the plasma.

The EUV radiation is collected and focused by a near normal incidence radiation collector 5 (sometimes referred to more generally as a normal incidence radiation collector). The collector 5 may have a multilayer structure that is arranged to reflect EUV radiation (e.g., EUV radiation having a desired wavelength such as 13.5 nm). The collector 5 may have an elliptical configuration, having two ellipse focal points. A first focal point may be at the plasma formation region 4, and a second focal point may be at an intermediate focus 6, as discussed below.

In other embodiments of a laser produced plasma (LPP) source the collector 5 may be a so-called grazing incidence collector that is configured to receive EUV radiation at grazing incidence angles and focus the EUV radiation at an intermediate focus. A grazing incidence collector may, for example, be a nested collector, comprising a plurality of grazing incidence reflectors. The grazing incidence reflectors may be disposed axially symmetrically around an optical axis.

The radiation source SO may include one or more contamination traps (not shown). For example, a contamination trap may be located between the plasma formation region 4 and the radiation collector 5. The contamination trap may for example be a rotating foil trap, or may be any other suitable form of contamination trap.

The laser 1 may be separated from the radiation source SO. Where this is the case, the laser beam 2 may be passed from the laser 1 to the radiation source SO with the aid of a beam delivery system (not shown) comprising, for example, suitable directing mirrors and/or a beam expander, and/or other optics. The laser 1 and the radiation source SO may together be considered to be a radiation system.

Radiation that is reflected by the collector 5 forms a radiation beam B. The radiation beam B is focused at point 6 to form an image of the plasma formation region 4, which acts as a virtual radiation source for the illumination system IL. The point 6 at which the radiation beam B is focused may be referred to as the intermediate focus. The radiation source SO is arranged such that the intermediate focus 6 is located at or near to an opening 8 in an enclosing structure 9 of the radiation source SO.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the reticle assembly 15 held by the support structure MT. The reticle assembly 15 includes a patterning device MA and a pellicle 19. The pellicle is mounted to the patterning device MA via a pellicle frame 17. The reticle assembly 15 may be referred to as a reticle and pellicle assembly 15. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 that are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system PS may include any number of mirrors (e.g., six mirrors).

The lithographic apparatus may, for example, be used in a scan mode, wherein the support structure (e.g., mask table) MT and the substrate table WT are scanned synchronously while a pattern imparted to the radiation beam is projected onto a substrate W (i.e., a dynamic exposure). The velocity and direction of the substrate table WT relative to the support structure (e.g., mask table) MT may be determined by the demagnification and image reversal characteristics of the projection system PS. The patterned radiation beam that is incident upon the substrate W may comprise a band of radiation. The band of radiation may be referred to as an exposure slit. During a scanning exposure, the movement of the substrate table WT and the support structure MT may be such that the exposure slit travels over an exposure field of the substrate W.

The radiation source SO and/or the lithographic apparatus that is shown in FIG. 1 may include components that are not illustrated. For example, a spectral filter may be provided in the radiation source SO. The spectral filter may be substantially transmissive for EUV radiation but substantially blocking for other wavelengths of radiation such as infrared radiation.

In other embodiments of a lithographic system the radiation source SO may take other forms. For example, in alternative embodiments the radiation source SO may comprise one or more free electron lasers. The one or more free electron lasers may be configured to emit EUV radiation that may be provided to one or more lithographic apparatus.

As was described briefly above, the reticle assembly 15 includes a pellicle 19 that is provided adjacent to the patterning device MA. The pellicle 19 is provided in the path of the radiation beam B such that radiation beam B passes through the pellicle 19 both as it approaches the patterning device MA from the illumination system IL and as it is reflected by the patterning device MA towards the projection system PS. The pellicle 19 comprises a thin film or membrane that is substantially transparent to EUV radiation (although it will absorb a small amount of EUV radiation). By EUV transparent pellicle or a film substantially transparent for EUV radiation herein is meant that the pellicle 19 is transmissive for at least 65% of the EUV radiation, preferably at least 80% and more preferably at least 90% of the EUV radiation. The pellicle 19 acts to protect the patterning device MA from particle contamination.

Whilst efforts may be made to maintain a clean environment inside the lithographic apparatus LA, particles may still be present inside the lithographic apparatus LA. In the absence of a pellicle 19, particles may be deposited onto the patterning device MA. Particles on the patterning device MA may disadvantageously affect the pattern that is imparted to the radiation beam B and therefore the pattern that is transferred to the substrate W. The pellicle 19 advantageously provides a barrier between the patterning device MA and the environment in the lithographic apparatus LA in order to prevent particles from being deposited on the patterning device MA.

The pellicle 19 is positioned at a distance from the patterning device MA that is sufficient that any particles that are incident upon the surface of the pellicle 19 are not in a field plane of the lithographic apparatus LA. This separation between the pellicle 19 and the patterning device MA acts to reduce the extent to which any particles on the surface of the pellicle 19 impart a pattern to the radiation beam B that is imaged onto the substrate W. It will be appreciated that where a particle is present in the beam of radiation B, but at a position that is not in a field plane of the beam of radiation B (for example not at the surface of the patterning device MA), then any image of the particle will not be in focus at the surface of the substrate W. In the absence of other considerations it may be desirable to position the pellicle 19 a considerable distance away from the patterning device MA. However, in practice the space which is available in the lithographic apparatus LA to accommodate the pellicle is limited due to the presence of other components. In some embodiments, the separation between the pellicle 19 and the patterning device MA may, for example, be approximately between 1 mm and 10 mm, for example between 1 mm and 5 mm, for example between 2 mm and 2.5 mm.

The pellicle may comprise a border portion and a membrane. The border portion of the pellicle may be hollow and generally rectangular and the membrane may be bounded by the border portion. As known in the art, the pellicle may be formed by deposition of one or more thin layers of material on a generally rectangular silicon substrate. The silicon substrate supports the one or more thin layers during this stage of the construction of the pellicle. Once a desired or target thickness and composition of layers has been applied, a central portion of the silicon substrate is removed by etching (this may be referred to as back etching). A peripheral portion of the rectangular silicon substrate is not etched (or alternatively is etched to a lesser extent than the central portion). This peripheral portion forms the border portion of the final pellicle while the one or more thin layers form the membrane of the pellicle (which is bordered by the border portion). The border portion of the pellicle may be formed from silicon.

Such a pellicle may require some support from a more rigid pellicle frame. The pellicle frame may provide two functions. First, the pellicle frame may support the pellicle and may also tension the pellicle membrane. Second, the pellicle frame may facilitate connection of the pellicle to a patterning device (reticle). It one known arrangement, the pellicle frame may comprise a main, generally rectangular body portion which is glued to the border portion of the pellicle and titanium attachment mechanisms that are glued to the side of this main body. Intermediate fixing members (known as studs) are affixed to the patterning device (reticle). The intermediate fixing members (studs) on the patterning device (reticle) may engage (for example releasably engage) with the attachment members of the pellicle frame.

The lithographic apparatus LA according to some embodiments of the present disclosure further comprising a heating system 20 operable to provide heat 22 to a pellicle 19 of a reticle and pellicle assembly 15 when supported by the support structure MT. The lithographic apparatus LA is advantageous, as now discussed.

One particularly promising material for use as a pellicle 19 membrane in an EUV lithographic apparatus is a fabric of carbon nanotubes (CNTs), which can provide very high EUV transmission (of >98%) and a very good mechanical stability. However, a low pressure hydrogen gas is typically provided within the lithographic apparatus LA, which forms a hydrogen plasma in the presence of the EUV radiation B (during exposure of the substrate W). It has been found that this hydrogen ions and hydrogen free radicals from the hydrogen plasma can etch pellicles 19 formed from CNTs, limiting the potential lifetime of the pellicle 19 and blocking commercial implementation of CNT pellicles.

The inventors of the present invention have realized that the etching of carbon by hydrogen ions and free radicals is temperature dependent. In particular, the inventors have realized that (a) the carbon etching rate is non-zero at lower temperatures; (b) the carbon etching rate falls to a negligible level at a threshold temperature above which the carbon etching remains at a negligible level; and (c) that a pellicle 19 within an EUV lithographic scanner will typically cycle through a range of temperatures sampling temperatures at which the carbon etching rate is not negligible during each cycle. For example, in an EUV lithographic scanner, during operation, an EUV radiation beam scans back and forth over the pellicle 19, which leads to permanent temperature fluctuations. If the temperature of the pellicle 19 is below the threshold temperature at which the carbon etching rate falls to a negligible level, even for part of the time during the scanning exposure, then the pellicle will degrade rapidly. Depending on various factors, it may be that there is a peak in the carbon etching rate at a temperature below the threshold temperature. If present, the peak in the carbon etching rate may be, for example, at a temperature between 600 K and 800 K. Furthermore, the fluctuations may be such that the temperature of the pellicle repeatedly crosses this peak, leading to enhanced degradation and a reduced lifetime of CNT pellicles 19. If the temperature of the pellicle during exposure of the reticle is maintained at a sufficiently high temperature then the rate of degradation can be maintained at low level and the pellicle lifetime is dramatically extended. As explained further below, the value above which it is desired to maintain the temperature of the pellicle may depend on various factors. It may be desirable to maintain the pellicle at a temperature above the threshold temperature although it will be appreciated that even by maintaining the pellicle at a temperature above a temperature which is close to but slightly below the threshold temperature may significantly reduce the rate of degradation of the pellicle. Furthermore, as also explained further below, the value of the threshold temperature may also depend on various factors. For example, it may be desirable to maintain the temperature of the pellicle permanently above 600, or more preferably above 700 K, or more preferably above 800 K. It is expected that by maintaining the temperature of the pellicle at a suitable temperature the rate of degradation can be reduced by at least an order of magnitude, dramatically extending the lifetime of the pellicle.

Advantageously, by providing a heating system 20 arranged to heat a pellicle of the reticle and pellicle assembly 15 supported by the support structure MT, the lithographic apparatus LA can ensure that the temperature of the pellicle 19, or at least any parts of the pellicle 19 which are adjacent the hydrogen plasma, can be maintained at a safe temperature at which the carbon etching rate is tolerable. For example, the safe temperature may be above the threshold temperature at which the carbon etching rate falls to a negligible level. It will be appreciated that the heating system 20 provides a mechanism to provide heat 22 to the pellicle 19 that is in addition to the heating provided by the radiation beam B from the illumination system IL.

Furthermore, by providing a heating system 20 arranged to heat a pellicle of the reticle and pellicle assembly 15 supported by the support structure MT, the lithographic apparatus LA can allow for better control of the temperature of the pellicle 19 and may allow a reduction in thermal cycling of the pellicle and any associated problems with such thermal cycling.

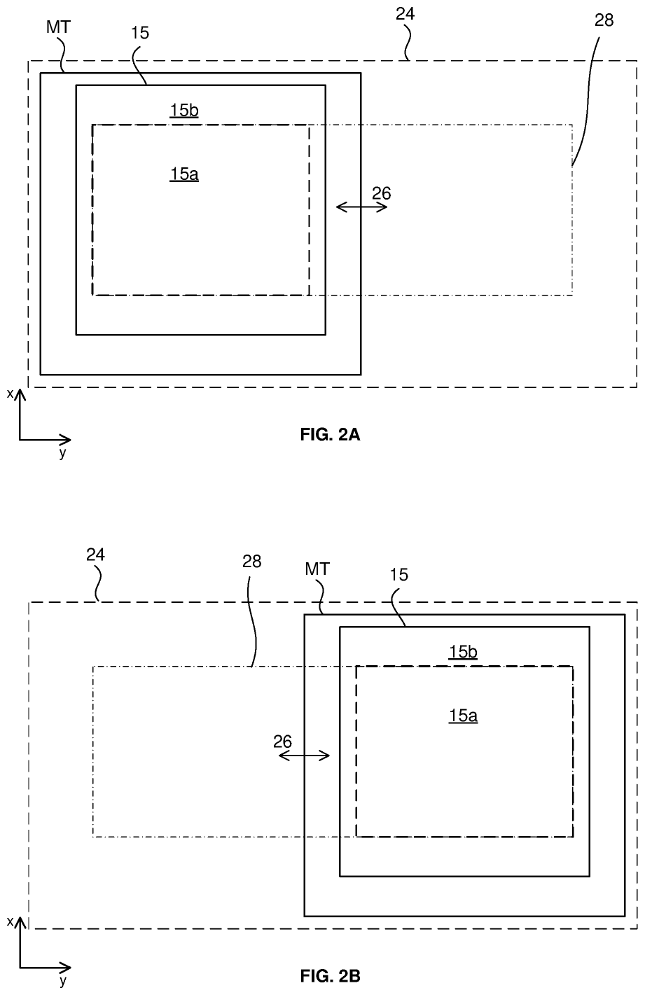

It will be appreciated that the heating system 20 is shown very schematically in FIG. 1 and that in practice the heating system 20 can take any suitable form. It may be particularly desirable to provide the heating system 20 such that it can be added into existing lithographic apparatus with minimal modification of the lithographic apparatus. That is, existing lithographic apparatus may provide some design constraints for at least some embodiments of the present disclosure. Therefore, with reference to FIGS. 2A to 4, we now provide a description of some features of an example type of lithographic apparatus, in particular some features and components that are close to the support structure MT.

The support structure MT may be movable in a scanning direction so as to expose a greater region of the patterning device MA of the reticle and pellicle assembly 15 in a single dynamic scanning exposure, as now discussed with reference to FIGS. 2A and 2B. FIGS. 2A and 2B show a schematic plan view of the support structure MT and the reticle and pellicle assembly 15 in two different positions.

The support structure MT is movably mounted within a region 24. In particular, the support structure MT is movable in a scanning direction, as indicated by arrow 26, between a first end position (as shown in FIG. 2A) and a second end position (as shown in FIG. 2B).

Unless stated otherwise, throughout this specification, the following set of Cartesian co-ordinates will be used. The scanning direction is labelled as the y-direction. A direction which is also in the plane of the support structure MT and is perpendicular to the scanning direction is referred to as the non-scanning direction and is labelled as the x-direction. A direction which is perpendicular to the plane of the support structure MT is labelled as the z-direction.

The lithographic apparatus LA may be considered to comprise a scanning module operable to move the support structure MT in the scanning direction between at least the first end position and the second end position. For example, the scanning module may be operable to move the support structure MT in the scanning direction relative to a supporting frame (indicated schematically by region 24), which the support structure MT may be considered to be movably mounted to.

The reticle and pellicle assembly 15 may be considered to comprise a central portion 15a and a peripheral portion 15b surrounding the central portion 15a. The central portion 15a may be referred to as an image formation portion and may coincide with a portion the reticle MA that patterns the radiation beam B and a membrane of the pellicle 19. The peripheral portion 15b may coincide with a border portion of the pellicle 19 and a frame of the pellicle 19.

The movement of the support structure MT between the first and second positions defines an extended first portion region 28 of the support structure MT defined by all of the regions that the central portion 15a of the reticle and pellicle assembly 15 can be disposed in. That is, the extended first portion region 28 of the support structure MT is a region defined by moving the central portion 15a of the reticle and pellicle assembly 15 from the first end position (as shown in FIG. 2A) to the second end position (as shown in FIG. 2B).

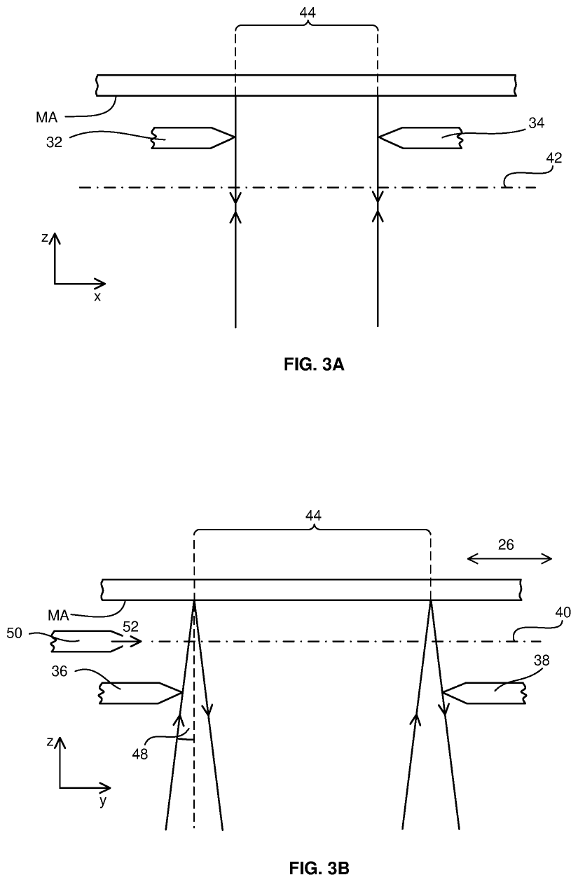

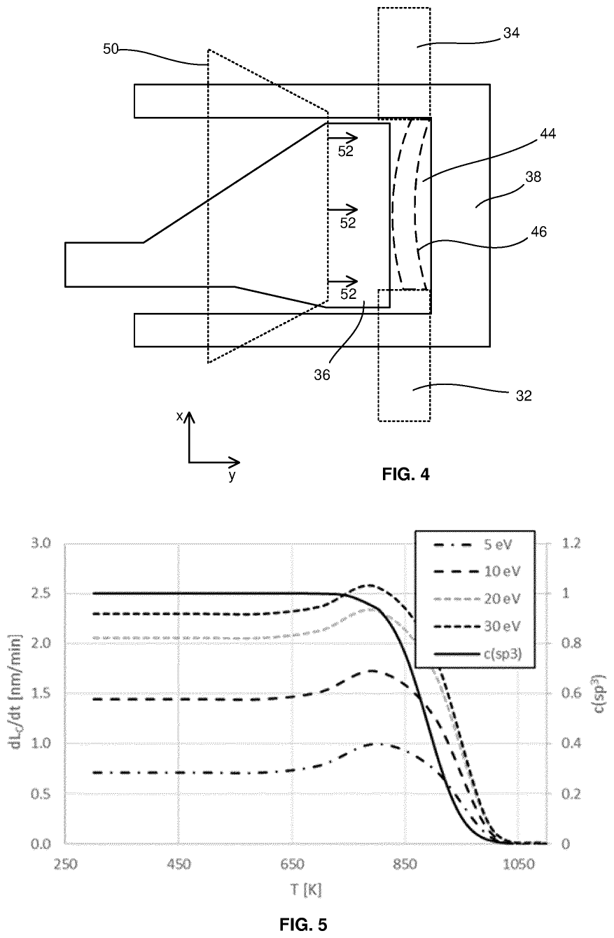

The lithographic apparatus LA is provided with four reticle masking blades, which define the extent of the field on the substrate W which is illuminated, as now described with reference to FIGS. 3A, 3B and 4. The illumination system IL is operable to illuminate a region of the patterning device MA when disposed on the support structure MT. This region may be referred to as the slit of the illumination system IL and is at least partially defined by four reticle masking blades, which define a generally rectangular region of the patterning device which can receive radiation. The extent of the generally rectangular region in a first direction, which may be referred to as the x direction, is defined by a pair of x masking blades 32, 34. The extent of the generally rectangular region in a second direction, which may be referred to as the y direction, is defined by a pair of y masking blades 36, 38.

Each of the masking blades 32, 34, 36, 38 is disposed close to, but slightly out of the plane of the patterning device on the support structure MT. The x masking blades 32, 34 are disposed in a first plane 40 and the y masking blades 36, 38 are disposed in a second plane 42.

Each of the masking blades 32, 34, 36, 38 defines one edge of a rectangular field region 44 in the plane of the patterning device MA which can receive radiation. In practice the illumination system IL may only illuminate part of the rectangular field region 44. As shown in FIG. 4, the illumination system IL may be arranged to illuminate a curved slit region 46, which may coincide with a part of the rectangular field region 44 (depending on the positions of the y masking blades 36, 38).

The curved slit region 46 may be partially defined by optics within the illumination system IL. In addition, the curved slit region 46 may be partially defined by a plurality of independently movable objects provided along one or both of the curved edges of the curved slit region 46. The plurality of independently movable objects may be referred to as fingers. The plurality of independently movable objects may be provided at different x positions and may be movable in the y direction to control an overlap between each of the movable objects and the radiation beam B produced by the illumination system IL. Controlling the y positions of the movable members may control a shape (or at least an intensity distribution) of one or both of the curved edges of the curved slit region 46. The movable members may be used to minimize variations in a dose of radiation provided by the radiation beam B at different positions in the non-scanning direction (i.e. the x direction). In addition, the curved slit region 46 may be partially defined by physical aperture, for example an entrance aperture of the projection system PS.

Each of the masking blades 32, 34, 36, 38 may be independently movable between a retracted position wherein it is not disposed in the path of the radiation beam and an inserted position wherein it at least partially blocks the radiation beam projected onto the patterning device MA by the illumination system IL. By moving the masking blades 32, 34, 36, 38 into the path of the radiation beam, the radiation beam B can be truncated (in the x and/or y direction) thus limiting the extent of the field region 44 which receives radiation beam B.

The x-direction corresponds to the non-scanning direction of the lithographic apparatus LA and the y-direction corresponds to the scanning direction of the lithographic apparatus LA. The patterning device MA is movable in the y-direction through the field region 44 (as indicated by again by arrow 26) so as to expose a greater region of the patterning device MA in a single dynamic scanning exposure.

During a dynamic exposure of a target region of a substrate W the target region is moved through an exposure region in the plane of the substrate W, the exposure region being a portion of the substrate W that the exposure region 44 of the patterning device MA is imaged onto by projection system PS. As the target region of the substrate W moves into the exposure region, the first masking blade 36, 38 moves such that only the target region receives radiation (i.e. no parts of the substrate outside of the target region are exposed). At the start of the scanning exposure one of the y masking blades 36, 38 is disposed in the path of the radiation beam B, acting as a shutter, such that no part of the substrate W receives radiation. At the end of the scanning exposure the other y masking blade 36, 38 is disposed in the path of the radiation beam B, acting as a shutter, such that no part of the substrate W receives radiation.

Rays of radiation beam B are shown adjacent to each of the masking blades 32, 34, 36, 38. It will be appreciated that each point in the slit region 46 is illuminated with radiation from a range of angles. For example, each point in the slit region 46 may receive a cone of radiation. The rays of radiation beam B are shown adjacent to each of the masking blades 32, 34, 36, 38 indicate an average direction of the radiation received by the patterning device MA. The rays of radiation beam B are shown adjacent to each of the masking blades 32, 34, 36, 38 may be referred to as chief rays. As can be seen from FIGS. 3A and 3B, in this embodiment, as projected onto the x-z plane, a chief ray of the radiation is generally normally incident on the patterning device MA whereas as projected onto the y-z plane, a chief ray of the radiation is generally incident on the patterning device MA at an angle 48.

The lithographic apparatus LA may further comprise a gas nozzle 50, which may be arranged to direct a flow of gas 52 adjacent to the support structure MT. In particular, the flow of gas 52 provided adjacent to the support structure MT by the gas nozzle 50 may be generally parallel to a surface of the patterning device MA and may be referred to as a cross-flow. The gas nozzle 50 may be disposed generally in the same plane (the first plane 40) as the x masking blades 32, 34. The gas nozzle may point in the scanning direction such that the flow of gas 52 is generally parallel to the scanning direction and flows between the x masking blades 32, 34. The gas nozzle 50 may be considered to form part of a gas supply module which is operable to provide a flow of gas adjacent to the support structure MT.

The gas nozzle 50 may form part of a hydrogen supply operable to supply hydrogen in the vicinity of the pellicle 19 of the pellicle and reticle assembly 15 when supported by the support structure MT.

FIG. 4 shows a plan view of the y masking blades 36, 38 in the second plane 42 as viewed in the positive z-direction (i.e. upwards in FIG. 3B). The position of the x masking blades 32, 34 and the gas nozzle (which are disposed in the first plane 40) are shown in dotted lines. In FIG. 4, the four masking blades 32, 34, 36, 38 are disposed so as to define a generally rectangular field region 44, the slit region 46 being disposed within this generally rectangular field region 44. This may be a typical configuration of the four masking blades 32, 34, 36, 38 during the exposure of a central portion of a target region (for example a die on a substrate W). As explained above, each of the x masking blades 32, 34 is operable to move in the x direction and each of the y masking blades 36, 38 is operable to move in the y direction to control the size of the field region 44. The y masking blades 36, 38 are configured such that they can be actuated from the same side of the field region 44. To achieve this, the y masking blades 36, 38 are shaped such that (although they lie in substantially the same plane 42) each of the y masking blades 36, 38 is provided with one or more support portions which extend in the same direction (the negative y direction in FIG. 4).

The masking blades 32, 34, 36, 38 and the gas nozzle 50 may be mounted on a common masking blade assembly support (not shown). It will be appreciated that the masking blades 32, 34, 36, 38 may be movably mounted on such a support such that they can move relative thereto. The gas nozzle may be statically mounted on such a support.

The lithographic apparatus LA may further comprise a controller 30 operable to control the heating system 20 so as to heat a pellicle 19 of the reticle and pellicle assembly 15 supported by the support structure MT so as to achieve a target temperature distribution.

The lithographic apparatus LA may further comprise a temperature sensor 31 operable to determine a temperature of at least a portion of the pellicle 19 of a pellicle and reticle assemble 15 supported by the support structure MT. The temperature sensor 31 may be operable to determine a temperature profile of at least a portion of the pellicle 19 of a pellicle and reticle assemble 15 supported by the support structure MT. The heating system 20 may be operable to heat the pellicle 19 of the reticle and pellicle assembly 15 supported by the support structure MT in dependence on a determined temperature or temperature profile of at least a portion of the pellicle 19. That is, the heating system 20 and the temperature sensor 31 may form part of a feedback loop (for example, via a controller 30).

The lithographic apparatus LA may be configured such that during exposure of a reticle and pellicle assembly 15 supported by the support structure MA to radiation B from the illumination system IL, the heating system 20 is configured to maintain at least a portion of the pellicle 19 of said reticle and pellicle assembly 15 above a minimum temperature.

The minimum temperature may be a threshold temperature above which a hydrogen etching rate of the pellicle 19 falls to a negligible level. It will be appreciated that the hydrogen etching rate of a pellicle 19 within a lithographic apparatus LA is dependent on a number of factors such as, for example: a material from which the pellicle 19 is formed; a flux of hydrogen ions incident on the pellicle 19; an energy distribution of ions that are incident on the pellicle 19.

As will be appreciated by the skilled person, within a lithographic apparatus, the hydrogen plasma is formed by the EUV radiation B (used for exposure of the substrate W). Therefore, at any given time, the at least a portion of the pellicle 19 of said reticle and pellicle assembly 15 which is maintained above a minimum temperature may comprise a portion of the pellicle that receives the EUV radiation from the illumination system IL. For example, the at least a portion of the pellicle 19 of said reticle and pellicle assembly 15 which is maintained above a minimum temperature may comprise the slit region 46 (see FIG. 4). It will be further appreciated that the plasma may extend to surrounding regions. Therefore, at any given time, the at least a portion of the pellicle 19 of said reticle and pellicle assembly 15 which is maintained above a minimum temperature may comprise a portion of the pellicle 19 that is centered on, but is slightly larger than, the portion of the pellicle that is within the slit region 46 and is receiving the EUV radiation from the illumination system IL.

In some embodiments, the at least a portion of the pellicle 19 of said reticle and pellicle assembly 15 which is maintained above a minimum temperature may comprise a portion of the pellicle 19 within the rectangular field region 44 defined by the masking blades 32, 34, 36, 38.

In some embodiments, the lithographic apparatus LA may be provided with a pellicle 19 formed from CNTs.

The interaction of hydrogen ions with carbon materials is described quantitatively in the following two published papers, the contents of which are hereby incorporated by reference: (1) J. Roth, C. García-Rosales, “Analytic description of the chemical erosion of graphite by hydrogen ions”, Nucl. Fusion 1996, 36/12, 1647-1659; and (2) J. Roth, C. García-Rosales, “Corrigendum-Analytic description of the chemical erosion of graphite by hydrogen ions”, Nucl. Fusion 1997, 37, 897. This quantitative description of the interaction of hydrogen ions with carbon materials may be referred to as Roth-García-Rosales (RGR) model. The RGR model can be used to predict an etch yield of carbon materials as function of the temperature for the typical hydrogen ion energies encountered within the lithographic apparatus such as, for example, ion energies form 1-30 eV. Within an EUV lithographic apparatus a typical hydrogen ion flux incident on the pellicle may be of the order of 1·10¹⁹ m⁻²·s⁻¹. Within an EUV lithographic apparatus a typical hydrogen ion flux incident on the pellicle may be within a couple of orders of magnitude of 1·10¹⁹ m⁻²·s⁻¹ (for example from 10¹⁸ m⁻²·s⁻¹ to 10²⁰ m⁻²·s⁻¹).

FIG. 5 shows an expected etching rate for hydrogen etching of carbon as a function of temperature for a hydrogen ion flux of 1.5·10¹⁹ m⁻²·s⁻¹ for four different ion energies: 5 eV, 10 eV, 20 eV and 30 eV. FIG. 5 also shows an sp3 carbon concentration as a function of temperature. From FIG. 5, it can be seen that for these typical ambient conditions in the lithographic apparatus LA, it is expected that for a pellicle formed purely from CNTs the hydrogen etching rate of the pellicle falls to a negligible level at a temperature of around 1050 K. However, it will be appreciated by the skilled person that under different conditions a different minimum temperature may be desirable.

In some embodiments, the minimum temperature is a temperature above which a hydrogen etching rate of the pellicle 19 falls to a negligible level. In some embodiments, the minimum temperature may be 1000 K or above. As explained above, this may be beneficial for a pellicle formed purely from CNTs wherein there is hydrogen ion flux incident on the pellicle may be of the order of 1·10¹⁹ m⁻²·s⁻¹ and the hydrogen ion energies are of the order of 1-30 eV. More preferably, the minimum temperature may be 1050 K or above. In some embodiments, the minimum temperature may be 1100 K or above.

A pellicle at such an elevated temperature, for example 1100 K, will radiate part of its energy to the surroundings. The heat that is radiated towards the reticle MA may in principle further heat up the reticle MA, which is undesirable. It is therefore useful to estimate this additional heat load on the reticle MA to assess whether or not it is acceptable. At a temperature of 1100 K the heat will be radiated so can be estimated using Planck's radiation formula:

$$p = ε \cdot σ \cdot ( {T}^{4} - {T}_{0}^{4} ) ,$$

where p is the power density, ε is an emissivity of the pellicle, σ is the Stefan-Boltzmann constant (5.67×10⁻⁸ W·K⁻⁴·m⁻²), T is the temperature of the pellicle and T₀ is the temperature of the reticle. The CNT pellicle is expected to act as a grey body radiator with an emissivity of ε=0.1 (a rather low number but still representing a worst case situation as current experimental CNT pellicles show emissivity values between 0.02 and 0.09). Using this, along with T=1100 K and T₀=300 K and yields p=0.8 W·cm⁻². The reticle MA is highly reflective for the emitted infrared (IR) radiation from the pellicle and is expected to reflect around 90% of this IR radiation. This means that a power density of 0.08 W·cm⁻² is expected to be absorbed by the reticle MA. Comparing this to the expected heat load on the reticle from the EUV radiation it is estimated that at current EUV radiation source powers the pellicle being at 1100 K will increase the heat load at the reticle by around 1-2%. For future, higher power EUV radiation sources the relative pellicle contribution will be even less. This additional heat load is therefore acceptable.

The inventors have further realized that the reduction of hydrogen etch rates to negligible levels at high temperatures is governed by the transformation of sp3 carbon into sp2 carbon at a given temperature (see FIG. 5). Furthermore, a similar process occurs when forming sp2 carbon structures such as graphene or CNTs, wherein a temperature of carbon is raised to transform it into sp2 carbon from which the sp2 carbon structures are formed. Such processes for growing graphene include, for example chemical vapor deposition (CVD) and plasma-enhanced chemical vapor deposition (PE-CVD). Furthermore, it is known that growth of graphene from sp3 carbon sources can be initiated at temperatures as low as 300° C. (573K) in the presence of single atoms catalyst. That is, conversion of sp3 carbon into sp2 carbon can be initiated at this temperature in the presence of single atoms of catalyst. Lowering the etch-free operating temperature range for the pellicle 19 is beneficial since it reduces the heat load to the environment of the pellicle 19. It also means that less heat has to be supplied to the pellicle 19 by the heating system 20, which may ease the systems providing this heat.

Therefore, it is proposed by the inventors of the present invention that pellicles 19 formed from CNTs should be provided with a concentration of additives which can act as a catalyst for conversion of sp3 carbon into sp2 carbon. As a result, it is expected that the threshold temperature above which a hydrogen etching rate of the pellicle 19 falls to a negligible level can be reduced from ˜1050K for pure CNT pellicles to, for example, of the order of 573K. It will be appreciated by the skilled person that the actual threshold temperature will be dependent on the material and concentration of the additives.

It is proposed to add transitional metal atoms to the CNT pellicles 19, such as, for example, molybdenum (Mo), chromium (Cr), nickel (Ni), copper (Cu), iron (Fe). Furthermore, it is expected by the inventors of the present invention that a relatively low concentration of such catalyst atoms, for example of the order of 0.1-1% with respect to carbon atoms may be sufficient. Such concentrations are not expected to have a significant impact on the transmission of EUV radiation through the pellicle 19.

Additionally or alternatively, it is proposed to add boron (B) to the CNT pellicles 19 with an atomic percentage of around 15%.

Additionally or alternatively, it is proposed to add amorphous carbon to the CNT pellicles 19.

The heating system 20 may be configured so as to heat a pellicle 19 of the reticle and pellicle assembly 15 supported by the support structure MT so that a combined heat load from the heating system 20 and the radiation beam B received from the illumination system achieves a target temperature distribution. For example, the heating system may be configured such that the entire pellicle is maintained at a desired temperature or temperature range (for example greater than 1050 K). Alternatively, a more selective, localized heating may be applied.

A first embodiment of a heating system 20 operable to provide heat 22 to a pellicle 19 of a reticle and pellicle assembly 15 when supported by the support structure MT is now described with reference to FIG. 6.

The lithographic apparatus LA is a scanning lithographic apparatus, as described above, comprising a support structure scanning mechanism operable to move the support structure MT relative to the radiation beam B conditioned by the illumination system IL so as to move a reticle and pellicle assembly 15 supported by the support structure through said radiation beam B. That is, the exposure of the substrate W is performed as a scanning exposure. It will be appreciated that a corresponding scanning mechanism is arranged to synchronously scan the substrate table WT (and any substrate W supported thereby) through the radiation beam B received from the projection system PS.

The heating system 20 is configured to heat at least a portion 56 of the pellicle 19 which is currently receiving the radiation beam B and a portion 54 of the pellicle 19 that is adjacent the portion 56 of the pellicle 19 which is currently receiving the radiation beam B. With this approach, that part of the pellicle 19 that is exposed to EUV radiation B, and hence that part of the pellicle 19 where the hydrogen ion flux is largest and the etching process might harm the pellicle 19 the most, can be maintained at a suitable temperature to prevent etching by the hydrogen ions.

As will be appreciated by the skilled person, within a lithographic apparatus LA, the hydrogen plasma is formed by the EUV radiation B (used for exposure of the substrate W). Therefore, at any given time, at least a portion of the pellicle 19 of said reticle and pellicle assembly which receives the EUV radiation B from the illumination system IL may be maintained above a minimum temperature.

Heating the pellicle 19 in the vicinity of the slit 46 is advantageous since in existing lithographic apparatus LA there may be line-of-sight towards the slit 46 from the illumination system IL and/or from the projection system PS. This may allow the heating system 20 to irradiate the pellicle 19 with radiation 60 so as to heat the pellicle 19.

In the example embodiment shown in FIG. 6, the heating system 20 comprises two radiation sources 20a, 20b, each operable to direct radiation 60a, 60b at the pellicle 19 of a reticle and pellicle assembly 15 when supported by the support structure MT. The radiation 60a, 60b may comprise electromagnetic radiation or an electron beam.

As explained above, in the lithographic apparatus LA there are various objects which may extend into the EUV radiation beam B and effectively clip the radiation beam B so as to define the curved slit region 46. These objects may include: fingers, a physical aperture and the masking blades 32, 34, 36, 38. All such objects, which are disposed between the illumination system IL and the pellicle, are represented schematically by box 58 in FIG. 6. These objects 58 will also limit the line-of-sight of the heating system 20. Therefore, the two radiation sources 20a, 20b should be arranged such that the radiation 60a, 60b emitted thereby spatially overlaps with the EUV radiation beam B at the location of any such beam clipping objects 58. Furthermore, since these objects 58 may be disposed at different z positions, the two radiation sources 20a, 20b should be arranged such that the radiation 60a, 60b emitted thereby spatially overlaps with the EUV radiation beam B over an extended range of z positions. It is for this reason that the heating system 20 comprises two radiation sources 20a, 20b, one on each side (in the scanning direction) of the radiation beam B.

As can be seen from FIG. 6, in this embodiment, the heating system 20 is configured to heat at least a portion 54 of the pellicle 19 surrounding the portion 56 of the pellicle 19 which is currently receiving the radiation beam B. It will be appreciated that the plasma may extend to such surrounding regions 54. Therefore, at any given time, the at least a portion of the pellicle 19 of said reticle and pellicle assembly 15 which is maintained above a minimum temperature may comprise a portion 54, 56 of the pellicle 19 that is centered on, but is slightly larger than, the portion 56 of the pellicle 19 that is receiving the EUV radiation B from the illumination system IL.

The choice of the wavelength for the radiation 60a, 60b may be such that the pellicle 19 absorbs a significant part of the radiation 60a, 60b, and transmits (to the reticle MA) as little radiation 60a, 60b as possible. For example, the radiation 60a, 60b may comprise infrared radiation. The radiation sources 20a, 20b of the heating system may be positioned such that they are outside the EUV radiation beam B, but incident on the pellicle 19 with a relatively small angle of incidence. The angle of incidence may, for example, in the range of around 0-20° in some embodiments. In some embodiments, the radiation sources 20a, 20b that produces the radiation 60a, 60b can be positioned outside the lithographic apparatus LA and directed towards the pellicle 19 using any suitable optical pathway (for example comprising optical fibers).

The first embodiment of a heating system 20 the heating system 20 may be configured to provide less heat to the portion 56 of the pellicle 19 which is currently receiving the radiation beam B than to the adjacent portion 54 of the pellicle. This may allow a generally uniform temperature to be achieved across both the portion 56 of the pellicle 19 which is currently receiving the radiation beam B than to the adjacent portion 54 of the pellicle despite the EUV heat load delivered to the portion 56 of the pellicle 19 which is currently receiving the radiation beam B.

A variant of the first embodiment of a heating system 20 is now described with reference to FIG. 7. The heating system 20 shown in FIG. 7 is generally identical to the heating system 20 shown in FIG. 6 except that in this variant the heating system 20 is configured to heat a portion 54 of the pellicle that is adjacent to the portion 56 of the pellicle 19 which is currently receiving the radiation beam B. In this embodiment the radiation 60a, 60b is not directed at the portion 56 of the pellicle 19 which is currently receiving the radiation beam B. Such a variant may be used for situations were the EUV radiation beam B provides sufficient heat to maintain the portion 56 of the pellicle 19 which is currently receiving the radiation beam B at a desired minimum temperature.

In a second example, embodiment the heating system 20 may be configured to heat substantially an entire membrane of the pellicle 19, as now discussed.

A potential problem of only heating the pellicle 19 in the region of the slit 46 may be an insufficient suppression of the etching just outside the slit 46. Although the hydrogen ion flux will rapidly decrease at pellicle locations outside the radiation slit 46, it may be that the combination of still having some ion flux and insufficient pellicle temperature will lead to some etching that affects life time of the pellicle 19 in a negative way.

This second embodiment can still be implemented using a radiation source. However, the technical realization of the heating system 20 will become more complex, as the access to the entire pellicle 19 can only be achieved via the sides of the pellicle 19 under small grazing angles of incidence. Nevertheless, similar laser light driven heating scheme can be envisaged either providing a radiation source in the vicinity of the support structure MT or using fiber optics to deliver radiation from a radiation source outside of the lithographic apparatus to the pellicle.

A fixed heating profile can be used to achieve a homogeneous pellicle 19 temperature. For example, regions of the pellicle 19 that are in the slit 46 may receive less radiation from the heating system 20 than other areas of the pellicle 19. Achieving a homogeneous pellicle 19 temperature over substantially the entire membrane of the pellicle 19 has the advantage of solving potential problems of mechanical fatigue of the pellicle 19 due to thermal cycling. Due to the space constraints within a lithographic apparatus, the radiation from the heating system 20 may be supplied to the pellicle at grazing incidence angles. This will result in lower absorption of the radiation because pellicle 19 reflectivity increases at such grazing incidence angles. A first consequence of this is that, for electromagnetic radiation sources, the radiation source of the heating system 20 may require more power than the radiation source used in the embodiment shown in FIG. 6 and described above. A second consequence of this is that less radiation is transmitted to the reticle MA, which beneficially lowers the additional heat load to the reticle MA provided by the heating system 20.

The reflectivity of the pellicle 19 for electron beams is lower than the reflectivity of the pellicle 19 for electromagnetic radiation at grazing incidence angles. Therefore, the use of an electron beam to provide the heat 22 from the heating system 20 has the advantage of delivering relatively more heat 22 to the pellicle 19 than an electromagnetic radiation source at a similar grazing incidence angle. Furthermore, by selecting an appropriate electron energy of the electron beam, the transmission of electrons from the electron beam through the pellicle 19 to the reticle MA can be reduced to negligible levels (so that there is no, or very little, additional heat load to the reticle MA from the heating system 20).

It will be appreciated that in order to heat substantially the entire membrane of the pellicle 19 the irradiated field should be large enough to do so despite the movement of the support structure MT. That is, the irradiated field may coincide with the extended first portion region 28 (see FIGS. 2A and 2B). Accommodating for this movement effectively doubles the irradiated area and will lead to heating of the support structure MT.

Some embodiments may further comprise a heating scanning mechanism operable to move at least one of the radiation source 20 and the support structure MT such that radiation emitted by the radiation source 20 can be directed at a range of different parts of a pellicle 19 of a reticle and pellicle assembly 15 when supported by the support structure MT. It will be appreciated that the heating scanning mechanism may be operable to account for both: (a) movement of the pellicle 19 (due to movement of the support structure MT); and (b) movement of the radiation 22 relative to the pellicle 19 (whether static or moving with the support structure MT).

For example, a system of galvano mirrors may be used to control a direction of electromagnetic radiation delivered to the pellicle 19 by the heating system 20. Similarly, a system of electron optics (for example magnets) may be used to control a direction of an electron beam delivered to the pellicle 19 by the heating system 20. Such systems offer better flexibility by modulating the light intensity or electron current: with such a heating scanning mechanism every part of the pellicle 19 can receive an optimized amount of heat load to generate a specific temperature profile.

A third example embodiment of the heating system 20 is arranged to supply an electrical current through the pellicle 19 of a pellicle and reticle assembly 15 when supported by the support structure MT. That is, in this third embodiment, the heating system 20 may be arranged to heat the pellicle 19 using Joule heating or electrical heating. Such embodiments use the electrical resistivity of the pellicle 19 itself to heat the pellicle 19.

The heating system may comprise a plurality of electrodes operable to contact different parts of the pellicle 19 of the reticle and pellicle assembly 15 and a power supply arranged to provide voltages across at least two of the plurality of electrodes.

For example, two strip-like electrodes may be provided along two opposed sides of the pellicle 19 and a voltage may be provided across the two electrodes. With such an arrangement, a current will flow between (and generally or approximately perpendicular to) the two electrodes from one of the opposed side of the pellicle to the other.

More complicated heating profiles can be applied, by using more electrodes and suitable voltage levels at these electrodes. Modulation of the voltages in time is also conceivable to obtain in principle any heat profile that is beneficial.

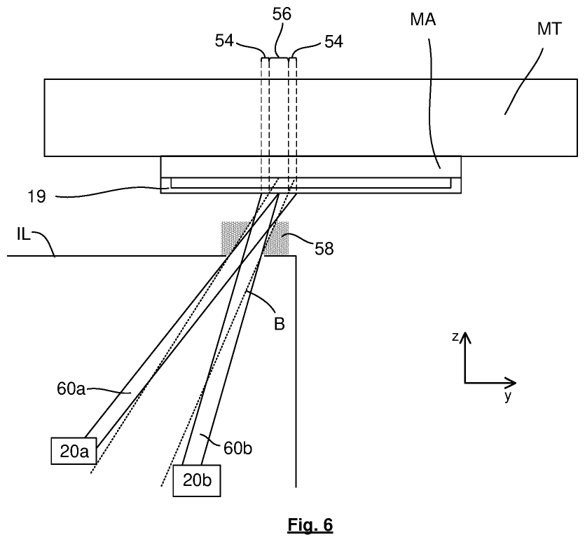

Another embodiment of a heating system 20 operable to provide heat 22 to a pellicle 19 of a reticle and pellicle assembly 15 when supported by the support structure MT is now described with reference to FIG. 8.

The lithographic apparatus LA may be a scanning lithographic apparatus, as described above, comprising a support structure scanning mechanism operable to move the support structure MT (as indicated by arrow 61 in FIG. 8) relative to the radiation beam B conditioned by the illumination system IL so as to move a reticle and pellicle assembly 15 supported by the support structure through said radiation beam B. That is, the exposure of the substrate W may be performed as a scanning exposure. It will be appreciated that a corresponding scanning mechanism is arranged to synchronously scan the substrate table WT (and any substrate W supported thereby) through the radiation beam B received from the projection system PS.

The heating system 20 comprises: an electrode 62; and a voltage supply 64. The voltage supply 64 is operable to apply a voltage across the electrode 62 and the pellicle 19 of a reticle and pellicle assembly when supported by the support structure MT.

The heating system 20 may further comprise: a heater 66 operable to heat the electrode 62 by supplying heat 68 to it. In use, the heater 66 is operable to maintain the temperature of the electrode 62 at a suitable temperature such that a thermal energy of electrons in the electrode 62 exceeds the work function of the material from which the electrode 62 is formed.

Advantageously, the arrangement shown in FIG. 8 allows for thermionic heating of the pellicle 19. In use, the voltage supply 64 may be such that the electrode 62 can act as a cathode and the pellicle 19 can act as an anode. With such an arrangement electrons 70 that are emitted by the cathode are directed towards the pellicle 19. The electrons 70 are attracted to the (positively charged) pellicle 19 and are not attracted to other parts of the lithographic apparatus LA. Therefore, one advantage of such thermionic heating is that the heating is targeted such that there is no or minimal heating of other parts of the lithographic apparatus LA. Another advantage of such thermionic heating is that the high heat transfers can be achieved.

In some embodiments, the voltage supply 64 may receive a control signal 72, for example from controller 30 (see FIG. 1). The voltage applied by the voltage supply 64 across the electrode 62 and the pellicle 19 of a reticle and pellicle assembly when supported by the support structure MT may be dependent on the control signal 72.

In the example embodiment shown in FIG. 8, the voltage supply 64 is operable to apply a voltage across the electrode 62 and the whole pellicle 19 of a reticle and pellicle assembly when supported by the support structure MT. For example, the pellicle 19 may comprise a continuous conducting layer and the voltage supply may be configured to apply a voltage to the conductive layer. Therefore, in this embodiment the heating system 20 is configured to heat substantially an entire membrane of the pellicle 19.

It will be appreciated that in some other embodiments, the voltage supply 64 may be operable to apply a voltage across the electrode 62 and one of a plurality of portions of the pellicle 19 of a reticle and pellicle assembly when supported by the support structure MT. For example, the pellicle may comprise a broken conducting layer comprising a plurality of separate conducting portions and the voltage supply 64 may be configured to apply a voltage to one or more of said plurality of conductive portions. Such alternative embodiments may allow the heating system 20 to heat a portion of the pellicle 19 which is currently receiving the radiation beam B and, optionally, a portion of the pellicle 19 that is adjacent the portion of the pellicle 19 which is currently receiving the radiation beam B in a manner similar to the embodiments described above with reference to FIGS. 6 and 7. With this approach, that part of the pellicle 19 that is exposed to EUV radiation B, and hence that part of the pellicle 19 where the hydrogen ion flux is largest and the etching process might harm the pellicle 19 the most, can be maintained at a suitable temperature to prevent etching by the hydrogen ions.

Furthermore, for such alternative embodiments wherein the voltage supply 64 is operable to apply a voltage across the electrode 62 and one of a plurality of portions of the pellicle 19 of a reticle and pellicle assembly when supported by the support structure MT, different voltages may be applied to different portions of the pellicle 19 so as to achieve different heating profiles.

Although shown schematically in FIG. 8 as a single electrode, it will be appreciated that in practice the electrode 62 may comprise more than one electrode. In some embodiments, a plurality of electrodes may be used to facilitate efficient heating of the pellicle 19 through a range of positions of the pellicle 19 in use taking into account the movement of the support structure MT.

FIG. 9 is a graph showing an estimation of the heating power of thermionic (dashed line) and radiation (dotted line) heating of a pellicle 19 as a function of the temperature of the radiator. It can be seen from FIG. 9 that for higher radiator temperatures thermionic heating is more efficient than radiation heating. In particular, for higher radiator temperatures above around 800 K, it is expected that thermionic heating will be more efficient than radiation heating.

As discussed above, pellicles 19 comprising a membrane formed from a fabric of carbon nanotubes (CNTs), which can provide very high EUV transmission (of >98%) and a very good mechanical stability. However, such pellicles 19 formed from CNTs are susceptible to hydrogen plasma etching within the lithographic apparatus LA. As also discussed above, it is expected that there is a threshold temperature above which a hydrogen etching rate of the CNT pellicle 19 falls to a negligible level. This temperature threshold is dependent on a number of factors but it may be of the order of 700° C. Therefore, as this etching process can be strongly suppressed by heating the CNT pellicle 19 continuously to over 700° C. This can significantly extend the potential lifetime of CNT pellicle 19, making the CNT pellicle a viable option. For example, it is expected that potential lifetime of CNT pellicle 19 could be extended to the exposure of over 10,000-20,000 silicon wafers W.

Such proposed supplementary heating for suppression of CNT pellicle 19 etching has some potential problems. First, as noted above, the space available in the vicinity of the reticle and pellicle assembly 15 when supported by the support structure MT in which the heating system 20 can be provided is limited. Second, it is generally desirable to minimize the additional heating load from the heating system 20 due to the finite amount of cooling that can be provided in the vicinity of the reticle and pellicle assembly 15 when supported by the support structure MT. Any additional heat load to the reticle MA can cause distortion of the reticle and may impact imaging performance of the lithographic apparatus LA. For example, such heat loads may have an impact on overlay. The power used to continuously heat the entire membrane of the pellicle 19 at a temperature in a range from 500 to 1000° C. may be of the order of 10 W or more, for example in a range from 10 to 500 W, more preferably from 50 to 200 W. Furthermore, a significant portion of this power may be delivered to the reticle MA or other surrounding components. Also when the entire membrane of the pellicle 19 is continuously heated portions of membrane in the slit region 46 may be redundantly heated, leading to unnecessary heat load in the vicinity of the reticle and pellicle assembly 15.

In some embodiments of the present disclosure the heating system 20 is operable to periodically heat the pellicle 19 of a reticle and pellicle assembly 15 when supported by the support structure MT. In some embodiments of the present disclosure the heating system 20 is operable to provide pulsed heating to the pellicle 19 of a reticle and pellicle assembly 15 when supported by the support structure MT. In particular, some embodiments of the present disclosure use low duty cycle pulsed (flash) heating of the pellicle 19 to achieve CNT pellicle lifetime improvement by etch rate suppression.

It will be appreciated that such periodic or pulsed heating will result in a periodically varying or pulsed temperature profile of the pellicle 19. However, the inventors have realized that once the pellicle 19 has been heated to above a threshold level (at which hydrogen etching becomes negligible), once the heating is removed, there is a time delay before the etching rate increases from the negligible level. It is has been found that, following a period of heating to a temperature at which hydrogen etching becomes negligible, once the heating is removed the hydrogen etch rate change over time generally as shown qualitatively in FIG. 10.

It is thought that heating to a sufficient temperature causes desorption of hydrogen from the pellicle 19, which reduces the hydrogen etching rate to negligible levels. Furthermore, it is thought that there is a time delay Δt in the increase in the etching rate after removal of the heating as it takes a non-zero time for the surfaces of the pellicle 19 to be replenished with hydrogen following the heating. This hydrogen replenishing rate may be proportional to the hydrogen radical flux to the membrane of the pellicle 19 within the lithographic apparatus LA. As the time since removal of the heating increases, eventually the etch rate rises to a typical value for a room temperature pellicle 19.

Advantageously, by only periodically heat the pellicle 19 of the reticle and pellicle assembly 15 and/or by providing pulsed heating to the pellicle 19 of the reticle and pellicle assembly 15 the power supplied by the heating system 20 is significantly reduced relative, for example, to an arrangement wherein the pellicle 19 is continuously heated. This reduces the additional heating load from the heating system 20 provided in the vicinity of the reticle and pellicle assembly 15 when supported by the support structure MT. In turn, this reduces the amount of power needed for the heating system 20 and the amount of cooling capacity that is needed to absorb the heat load. It also reduces the additional heat load to the reticle MA which can cause distortion of the reticle MA and may impact imaging performance of the lithographic apparatus LA (for example such heat loads may contribute to overlay).

Furthermore, by only periodically heating the pellicle 19 of the reticle and pellicle assembly 15 and/or by providing pulsed heating to the pellicle 19 of the reticle and pellicle assembly 15, the heating system 20 may operate in between exposures in the lithographic apparatus LA. For example, the heating system 20 may operate in between exposures of different target regions (or dies) of a single substrate W or even in between exposures of different substrates W. In turn, by allowing for heating in between exposures, the heating system 20 may be located differently to an arrangement wherein it is desirable to heat the pellicle 19 during exposure of a substrate W. Advantageously, this may make integration of the heating system 20 into the lithographic apparatus LA easier as there may be more space to accommodate the heating system 20 in a location that, for example, can heat the pellicle 19 when the support structure WT is in a non-exposure position or location.

In general, a duration of the heating pulse may be sufficiently large to heat the pellicle 19 to a desired temperature (for example above a threshold temperature above which hydrogen etching of the pellicle is negligible). For example, it may be desirable to heat the pellicle 19 to a temperature of the order of 700° C. or above or a temperature of the order of 800° C. It will be appreciated that the time required for heating the pellicle 19 to a desired temperature will be dependent on a power of the heating system 20 while it is heating the pellicle 19. For example, the duration of the heating pulse can range from 0.1 ms to 100 ms, more preferably from 1 to 10 ms. In some embodiments, a duration of the heating pulse may be of the order of 1 ms.

In general, a time period between two consecutive heating pulses may be sufficiently small so as to not allow a surface of the pellicle 19 to become replenished with hydrogen following the heating from the first pulse. Put differently, the time period between two consecutive heating pulses may be less than the time delay Δt in the increase in the etching rate after removal of the heating (see FIG. 10). Again, it will be appreciated that the time required for the surface of the pellicle 19 to become replenished with hydrogen following the heating from the first pulse will be dependent on conditions in the vicinity of the pellicle 19. As explained above, this hydrogen replenishing rate may be proportional to the hydrogen radical flux to the membrane of the pellicle 19 within the lithographic apparatus LA. Taking into account some variability in radical flux in a high power lithographic apparatus it has been determined that the time that may be needed in between heating pulses may range from two dies (back and forth) to an entire wafer exposure. In terms of time in between heating pulses this is in a range from 50 ms to 20 seconds, more preferably from 100 ms to 10 seconds. In some embodiments, a time period between two consecutive heating pulses may be of the order of 100 ms.

It is thought that within an EUV lithographic apparatus LA, the hydrogen etching of a CNT pellicle 19 can be maintained at an acceptable or negligible level by providing periodic or pulsed heating for a very small fraction of the time. Therefore, in some embodiments, the heating of the pellicle 19 of the reticle and pellicle assembly 15 supported by the support structure MT provided by the heating system 20 comprises a relatively low duty cycle pulsed heating, as now discussed.

In the following a heating duty cycle of a heating system 20 is intended to mean a ratio of: (a) a fraction of time during which the heating system provides heating to the pellicle; to (b) a fraction of time during which the heating system provides no heating to the pellicle. In some embodiments the duty cycle of the heating system 20 is 0.1 or less. Advantageously, such an arrangement would reduce the amount of power provided by the heating system 20 by a factor of 10 relative to an arrangement wherein the pellicle is heated continuously. Previous simulations have shown that continuous heating of the pellicle to a temperature in excess of 700° C. may be expected to have an impact of the order of 0.2 nm on overlay, which can be mitigated by providing greater cooling to the reticle MA (for example by lowering a temperature of water used to the reticle MA). With periodic heating of the pellicle 19 with a heating duty cycle of 0.1 or less, the reduction in the heat load of a factor of 10 will, in turn, reduce the impact on overlay by at least a factor of 10, which may obviate the need to provide any additional cooling to the reticle MA. In fact, as explained below, even smaller heating duty cycles may be possible, which may make the overlay impact practically negligible.

A duty cycle of the heating system 20 of 0.1 or less is thought to be sufficient to maintain the hydrogen etching of the pellicle at an acceptable or negligible level even for the worst case scenario for conditions within an EUV lithographic apparatus LA.

However, it is thought that in practice even smaller duty cycles will be sufficient to maintain the hydrogen etching of the pellicle 19 at an acceptable or negligible level. For example, in some embodiments, the duty cycle of the heating system 20 may be 0.01 or less. In some embodiments, the duty cycle of the heating system 20 may be 10⁻³ or less. In some embodiments, the duty cycle of the heating system 20 may be 10⁻⁴ or less. In some embodiments, the duty cycle of the heating system 20 may be 10⁻⁵ or less.

During the scanning exposure of a plurality of target regions of a substrate W, the parts of the pellicle 19 that move through the slit region 46 (see FIG. 4) will be periodically heated by the EUV radiation beam B (see FIG. 1). As each target region (which may be a single die) of the substrate W is exposed (i.e. an image of the reticle MA is formed on that target region) each part of the pellicle from the central portion 15a of the reticle and pellicle assembly 15 (see FIGS. 2A and 2B) will receive a pulse of heating from the EUV radiation beam B. For a lithographic apparatus having an EUV radiation beam B power at the intermediate focus 6 (see FIG. 1) of 600 W and a standard reticle scan-speed, it is estimated that each part of the pellicle from the central portion 15a of the reticle and pellicle assembly 15 will experience a heating cycle of from 1 to 10 ms of heating (from the EUV radiation beam B) followed by a time cold in a range from 10 to 100 ms. That is, parts of the pellicle 19 from the central portion 15a of the reticle and pellicle assembly 15 are expected to experience a heating duty cycle of approximately 0.04. Therefore, as long as the EUV radiation beam B heats the pellicle to a sufficiently high temperature during the exposure of each target region or die (for example a temperature of at least 700° C.), the periodic heating from the EUV radiation beam B is expected to be sufficient to suppress hydrogen etching in the exposed part of the pellicle 19 (i.e. the part of the pellicle from the central portion 15a of the reticle and pellicle assembly 15).

Therefore in EUV lithographic apparatus LA having a radiation source SO with an EUV power >600 W it is expected that the pellicle 19 heating by EUV-absorption alone is sufficient to suppress hydrogen etching in the exposed part of the pellicle 19. However, hydrogen plasma also exists adjacent other parts of the pellicle 19 that are outside the EUV radiation beam B, such that there may exist a region of elevated etching that limits the lifetime of the pellicle 19.

Therefore, in some embodiments, the heating system 20 is configured to heat a portion of the pellicle 19 that does not, in use, receive the radiation beam B conditioned by the illumination system IL. That is, the heating system 20 may be configured to heat a portion of the pellicle 19 from the peripheral portion 15b of the reticle and pellicle assembly 15. In other embodiments, the heating system 20 may be configured to heat substantially an entire membrane of the pellicle 19.

In general, the embodiments wherein the heating system 20 is arranged to only periodically heat the pellicle 19 of the reticle and pellicle assembly 15 and/or by providing pulsed heating to the pellicle 19 of the reticle and pellicle assembly 15, the heating system 20 is configured to maintain at least a portion of the pellicle 19 of said reticle and pellicle assembly 15 above a minimum temperature. The minimum temperature may be a temperature at which a hydrogen etching rate of the pellicle 19 is negligible. For example, the minimum temperature may be 700° C. or above. In other embodiments, the minimum temperature may be 750° C. or above. In other embodiments, the minimum temperature may be 800° C. or above.

The relatively heating low duty cycle that is expected to be sufficient to suppress hydrogen etching of the CNT pellicle 19 has a number of consequences.

First, it allows the heating system 20 to be configured to heat a portion of the pellicle 19 which is not currently receiving the radiation beam B. In particular, it allows the heating system 20 to be configured to heat only a portion of the pellicle 19 which is not currently receiving the radiation beam B. In a scanning lithographic apparatus having a scanning mechanism operable to move the support structure MT relative to the radiation beam B conditioned by the illumination system IL so as to move a reticle and pellicle assembly 15 supported by the support structure MT through said radiation beam B, the heating system 20 being configured to heat a portion of the pellicle 19 which is not currently receiving the radiation beam B may allow the heating system to provide heat to the pellicle 19 when it is disposed in one of the two end positions shown in FIGS. 2A and 2B.

Second, for embodiments wherein the lithographic apparatus LA is operable to form an image of a reticle MA of the reticle and pellicle assembly 15 supported by the support structure MT on a plurality of different target regions (for example dies) of a substrate W supported by the substrate table WT, the heating system 20 may be operable to heat each part of the pellicle 19 that is heated once per exposure of every n target regions, where n is an integer. In some embodiments, n may be greater than 1. By only heating each part of the pellicle 19 that is heated once per exposure of every n target regions, the heating system 20 may be located differently to an arrangement wherein the pellicle 19 is continuously heated during exposure of a substrate W. For example, in a scanning lithographic apparatus LA, during exposure of one target region of a substrate W the support substrate MT is moved (or scanned) through the path of the radiation beam B conditioned by the illumination system IL from a first end position (see FIG. 2A) to a second end position (see FIG. 2B). Typically, for exposure of the next target region of the substrate W the support substrate MT is moved back through the path of the radiation beam B from the second end position to the first end position. Providing line of sight to the pellicle 19 when it is being exposed to the radiation beam B (in between the positions shown in FIGS. 2A and 2B) is challenging. However, there is typically more space to provide heating to the pellicle 19 when the support structure is disposed in one of the first or second end positions (i.e. FIG. 2A or FIG. 2B). Advantageously, by only heating each part of the pellicle 19 that is heated once per exposure of every n target regions, the heating system 20 can be configured to heat the pellicle 19 (or a portion thereof) when the pellicle 19 is in one of the first or second end positions (i.e. FIG. 2A or FIG. 2B). This makes integration of the heating system 20 into the lithographic apparatus LA easier as there may be more space to accommodate the heating system 20 in a location that, for example, can heat a part of the pellicle 19 that is not currently being exposed to the EUV radiation.

In some embodiments, the heating system 20 may be operable to heat each part of the pellicle 19 that is heated once per exposure of every 4 target regions. Heating the pellicle 19 after exposure of every 4 dies is thought to be sufficient to maintain the hydrogen etching of the pellicle 19 at an acceptable or negligible level even for the worst case scenario for conditions within an EUV lithographic apparatus LA. However, it is thought that in practice less frequent heating will be sufficient to maintain the hydrogen etching of the pellicle 19 at an acceptable or negligible level. For example, in some embodiments, the heating system 20 may be operable to heat each part of the pellicle 19 that is heated once per exposure of every 10 target regions. In some embodiments, the heating system 20 may be operable to heat each part of the pellicle 19 that is heated once per exposure of every 100 target regions. In some embodiments, the heating system 20 may be operable to heat each part of the pellicle 19 that is heated once per exposure of every 1000 target regions.

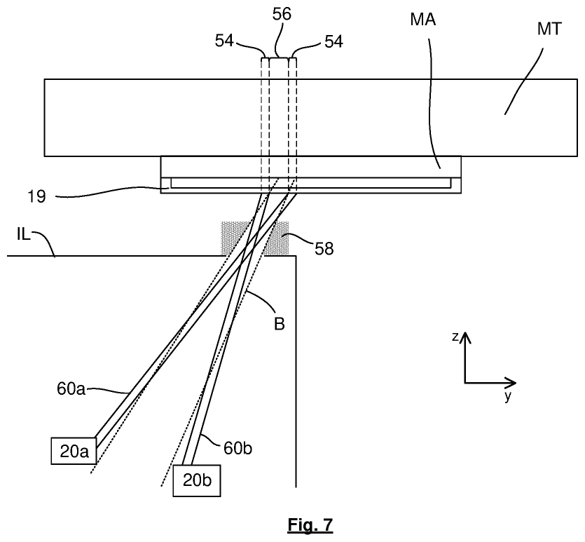

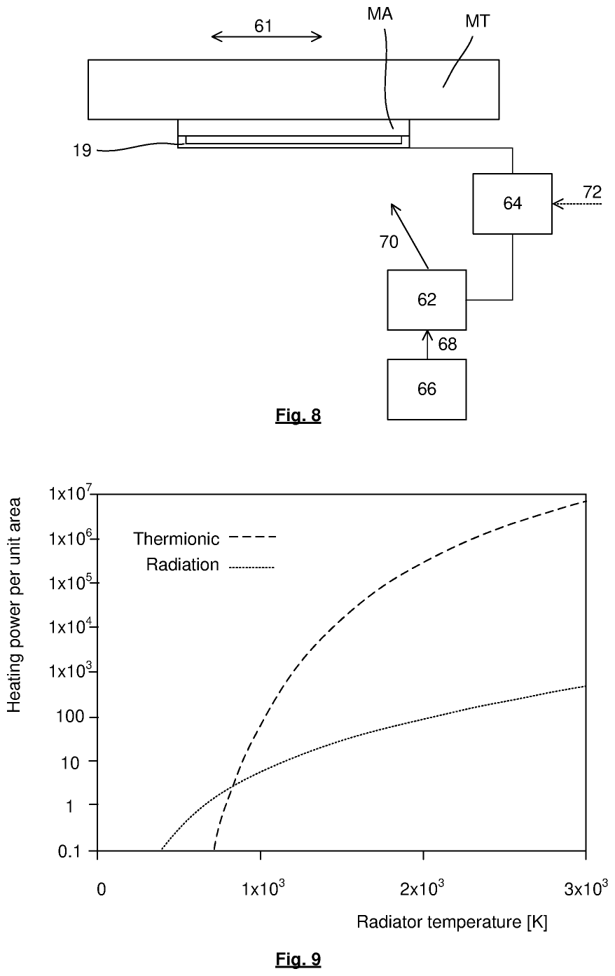

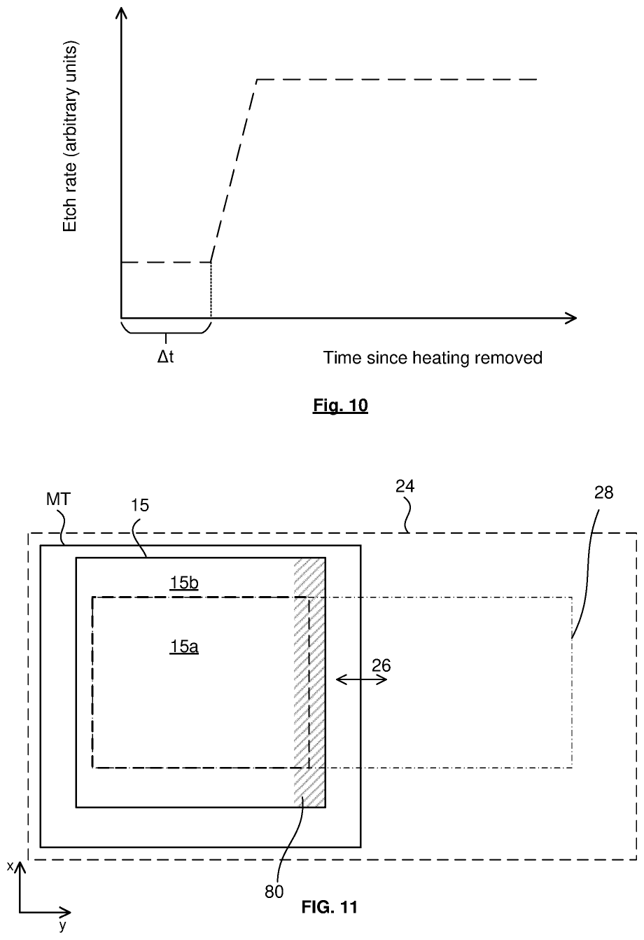

In some embodiments wherein the heating system 20 is operable to heat each part of the pellicle 19 that is heated once per exposure of every n target regions of the substrate W, the heating system 20 may be operable to heat each part of the pellicle 19 that is heated in a time between: the formation of an image of the reticle MA on one target region of the substrate W; and the formation of an image of the reticle MA on the next target region of the substrate W. For example, all parts of the pellicle 19 that it is desired to heat may be heated when the reticle and pellicle assembly 15 is disposed in one of the two end positions shown schematically in FIGS. 2A and 2B. Alternatively, as will be discussed below with reference to FIGS. 11 to 19B, in some other embodiments the wherein the heating system 20 is operable to heat each part of the pellicle 19 that is heated once per exposure of every n target regions of the substrate W, the heating system 20 may use the movement of the support structure MT that scans the reticle through the EUV radiation beam B to also scan the pellicle 19 through a heating beam.

In some embodiments, the heating duty cycle that is needed to ensure sufficient suppression of hydrogen etching of the CNT pellicle 19 may be sufficiently low that the heating system 20 is operable to heat the pellicle 19 in between exposure of one substrate W and a subsequent substrate W. This may be achieved without impacting throughput of the lithographic apparatus.

Some embodiments of a heating system 20 that is suitable for periodically heating the pellicle 19 of the reticle and pellicle assembly 15 and/or by for providing pulsed heating to the pellicle 19 of the reticle and pellicle assembly 15 are now discussed with reference to FIGS. 11 to 19B.

In general, a heating system 20 that is suitable for periodically heating the pellicle 19 of the reticle and pellicle assembly 15 and/or by for providing pulsed heating to the pellicle 19 of the reticle and pellicle assembly 15 can be arranged to provide heating to the pellicle outside of the slit region 46 and the field region 44 (see FIG. 4). The heating system 20 may be arranged to heat at least a part of the pellicle 19 when the support structure MT is disposed in the first end position (as shown in FIG. 2A) and/or the second end position (as shown in FIG. 2B). In particular, when the support structure MT is disposed in one of the first or second end positions the heating system 20 is operable to heat a portion of the reticle and pellicle assembly 15 that is closest to the slit region 46, as now discussed with reference to FIG. 11. FIG. 11 shows the same schematic plan view of the support structure MT and patterning device MA disposed in the first end position as shown in FIG. 2A. The heating system 20 in some embodiments is arranged so as to heat a portion 80 of the reticle and pellicle assembly 15 that is closest to the slit region 46 when the support structure MT is disposed in the first end position. With such an arrangement, during the usual scanning motion of the support structure MT from the first end position to the second end position, the entire reticle and pellicle assembly 15 can be heated by the heating system 20.

In general, for embodiments wherein the heating system 20 that is configured to periodically heat the pellicle 19 of the reticle and pellicle assembly 15 and/or by to provide pulsed heating to the pellicle 19 of the reticle and pellicle assembly 15, the heating system comprises one or more radiation sources. The radiation source(s) are typically electromagnetic radiation sources. The radiation source(s) may be referred to as light source(s). Suitable radiation sources include: (i) light emitting diodes (LEDs); and (ii) lasers (for example a vertical-cavity surface-emitting laser, VC SEL). Advantageously, both LEDs and the lasers can be built in a very small volume.

Lasers can be used to heat the pellicle 19 under a glancing angle such that the absorption rate can be increased and that the power can be limited. This also limits the power provided to the reticle MA and consequently undesirable deformation of the reticle MA. LEDs radiate more diverging light so embodiments using LEDs may be used to heat the pellicle 19 from a relatively short distance. However, with suitable beam guiding apparatus (such as optical fibers, mirrors and so on) light from LEDs can be guided to the pellicle 19 at a non-zero angle.

In some embodiments, the heating system 20 may further comprise a heat sink arranged to absorb any light from the heating system 20 that is reflected by the pellicle 19. Advantageously, this can avoid heating of critical components in the environment (such as the reticle MA). The heat can be caught in an absorbing layer or structure and then absorbed and removed by a water flow.

In general, the heaters (light sources) and the heatsinks can be placed on any components that allow for line of sight with the pellicle (and preferably allow for line of sight with the portion 80 of the reticle and pellicle assembly 15 that is closest to the slit region 46 when the support structure MT is disposed in the first end position; see FIG. 11). Suitable components that may support parts of the heating system 20 for such embodiments include: (a) a shield which is arranged to protect the reticle and pellicle assembly 15 from the fingers system; (b) the x masking blades 32, 34 (see FIGS. 3 and 4); (c) the gas nozzle 50 (see FIG. 4) arranged to provide a gas flow near the reticle and pellicle assembly 15; and/or (d) a spoiler that is arranged to guide hydrogen flow near the reticle and pellicle assembly 15. In general, the light sources of the heating system 20 can be arranged to direct radiation to the pellicle 19 either generally perpendicular to the pellicle 19 or at a grazing incidence angle (although since the x masking blades 32, 34 are open during exposure of a substrate W, when disposed on the x masking blades 32, 34 the light sources will generally direct radiation to the pellicle at a grazing incidence angle).

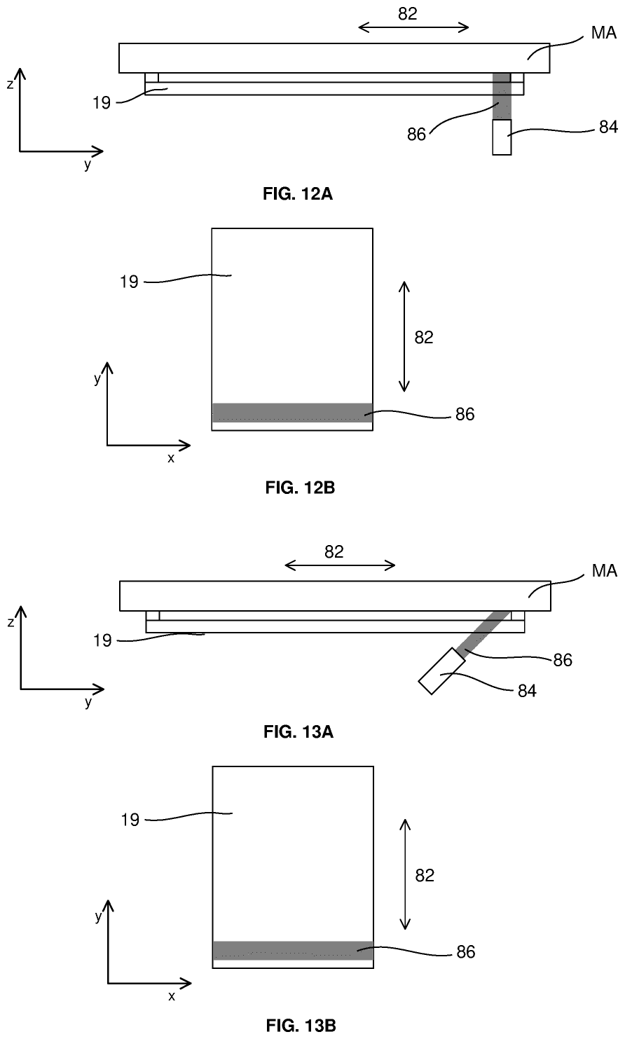

FIGS. 12A to 19B all show, schematically, embodiments of the heating system 20 that is operable to heat each part of the pellicle 19 that is heated once per exposure of every n target regions of the substrate W. In each embodiment, the heating system 20 uses the movement of the support structure MT that scans the reticle through the EUV radiation beam B to also scan the pellicle 19 through a heating beam. In each embodiment, the lithographic apparatus LA is a scanning lithographic apparatus, as described above, comprising a support structure scanning mechanism operable to move the support structure MT (as indicated by arrow 82 in FIGS. 12A to 19B) relative to the radiation beam B conditioned by the illumination system IL so as to move a reticle and pellicle assembly 15 supported by the support structure through said radiation beam B. That is, the exposure of the substrate W may be performed as a scanning exposure. It will be appreciated that a corresponding scanning mechanism is arranged to synchronously scan the substrate table WT (and any substrate W supported thereby) through the radiation beam B received from the projection system PS.

The embodiment shown in FIGS. 12A and 12B comprises a radiation source 84. The radiation source 84 may comprise one or more LEDs and/or one or more lasers. The radiation source 84 is operable to project a radiation curtain 86 onto the pellicle. It will be understood that the radiation source 84 may be operable to project radiation onto the portion 80 of the reticle and pellicle assembly 15 that is closest to the slit region 46 when the support structure MT is disposed in the first end position (see FIG. 11). The radiation source 84 may comprise a single radiation source. Alternatively, the radiation source 84 may comprise a plurality of radiation sources (for example separated in the non-scanning direction). The radiation source 84 is operable to direct the radiation curtain 86 at the pellicle 19 such that it is generally normally incident on the pellicle 19.

The radiation source 84 may be operable to output a radiation with a wavelength typical for ultraviolet radiation (for example having a wavelength in a region of absorption peaks from 200 to 400 nm) or infrared radiation (for example having a wavelength of from 1 μm to 20 μm, preferably from 1 to 10 μm). A desired extent of the radiation curtain 86 in the scanning direction (the y-direction in the Figures) may be dependent on the scanning speed of the support structure MT.

It may be desirable to heat the pellicle 19 to a temperature in a range from 500 to 1000 C, such as 800° C. In order to achieve this in 3 ms the power density of the radiation curtain 86 may be 5 to 30 kW/m², more preferably from 7.5 to 25 kW/m². In order to heat the entire pellicle 19, for a pellicle having an extent in the non-scanning direction (the x-direction in the Figures) of 11 cm, the total heating power may be of the order of 8 W. However, as explained above, in some embodiments, it may only be necessary to heat a peripheral portion 15b of the reticle and pellicle assembly 15. If only a peripheral portion 15b of the reticle and pellicle assembly 15 is heated, say only an outer 10 mm of the reticle and pellicle assembly 15, then the total heating power may be of the order of 1.4 W.

The embodiment shown in FIGS. 13A and 13B is the same as that shown in FIGS. 12A and 12B expect that, in FIGS. 13A and 13B, the source 84 is operable to direct the radiation curtain 86 at the pellicle 19 such that it is incident on the pellicle 19 at a grazing incidence angle, with a direction of the radiation having a component in the scanning direction (i.e. the y-direction).

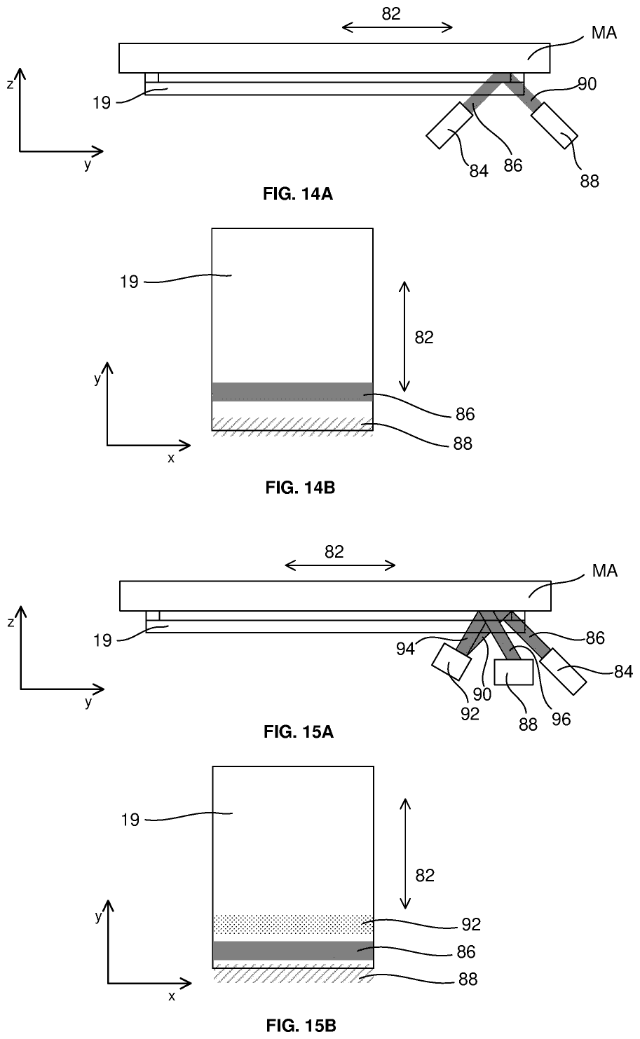

The embodiment shown in FIGS. 14A and 14B is the same as that shown in FIGS. 13A and 13B expect that, the embodiment shown in FIGS. 14A and 14B further comprises a beam dump 88. The beam dump 88 is arranged to absorb at least a portion of radiation 90 reflected by the reticle and pellicle assembly 15. A projection of the beam dump 88 onto the pellicle 19 is also shown in FIG. 14B.

The embodiment shown in FIGS. 15A and 15B is the same as that shown in FIGS. 13A and 13B expect that, the embodiment shown in FIGS. 15A and 15B further comprises: a beam dump 88 and a mirror 92. The mirror 92 is arranged to reflect at least a portion of radiation 90 reflected by the reticle and pellicle assembly 15 back to the reticle and pellicle assembly 15 as reflected beam 94. The beam dump 88 is arranged to absorb at least a portion 96 of the reflected beam 94 that is reflected by the reticle and pellicle assembly 15. Projections of the beam dump 88 and the mirror 92 onto the pellicle 19 are also shown in FIG. 15B.

The embodiment shown in FIGS. 16A and 16B is the same as that shown in FIGS. 12A and 12B expect that, in FIGS. 16A and 16B, the source 84 is operable to direct the radiation curtain 86 at the pellicle 19 such that it is incident on the pellicle 19 at a grazing incidence angle, with a direction of the radiation having a component in the non-scanning direction (i.e. the x-direction).

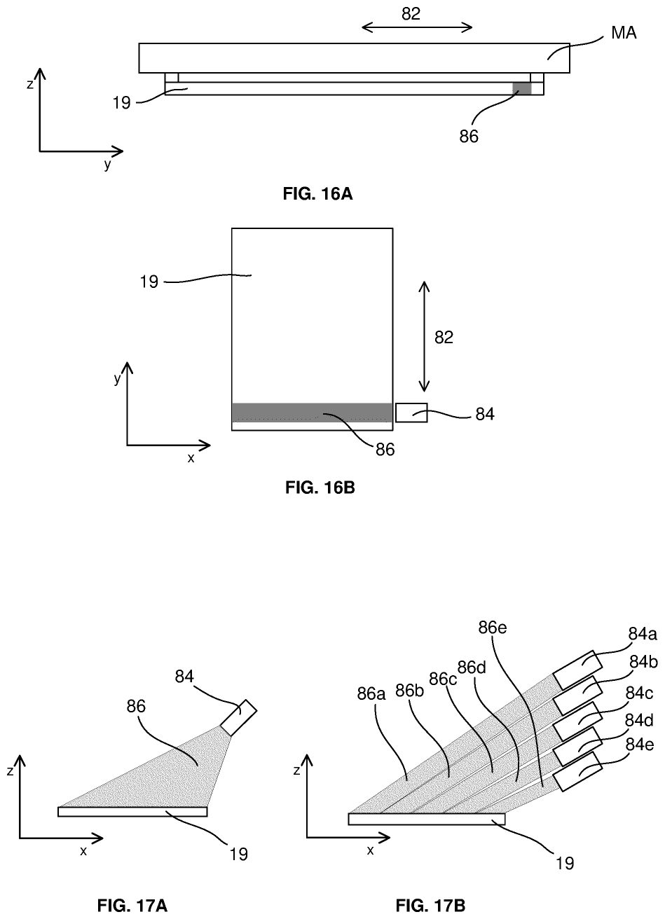

The embodiment shown in FIGS. 16A and 16B shows a single radiation source 84 although such embodiments may alternatively comprise a plurality of radiations sources. FIG. 17A shows an arrangement, in the x-z plane, wherein a single radiation source 84 is operable to generate the entire radiation curtain 86. FIG. 17B shows an arrangement, in the x-z plane, wherein a plurality of radiation sources 84a-84e are each operable to generate a portion 86a-86e of the radiation curtain 86.

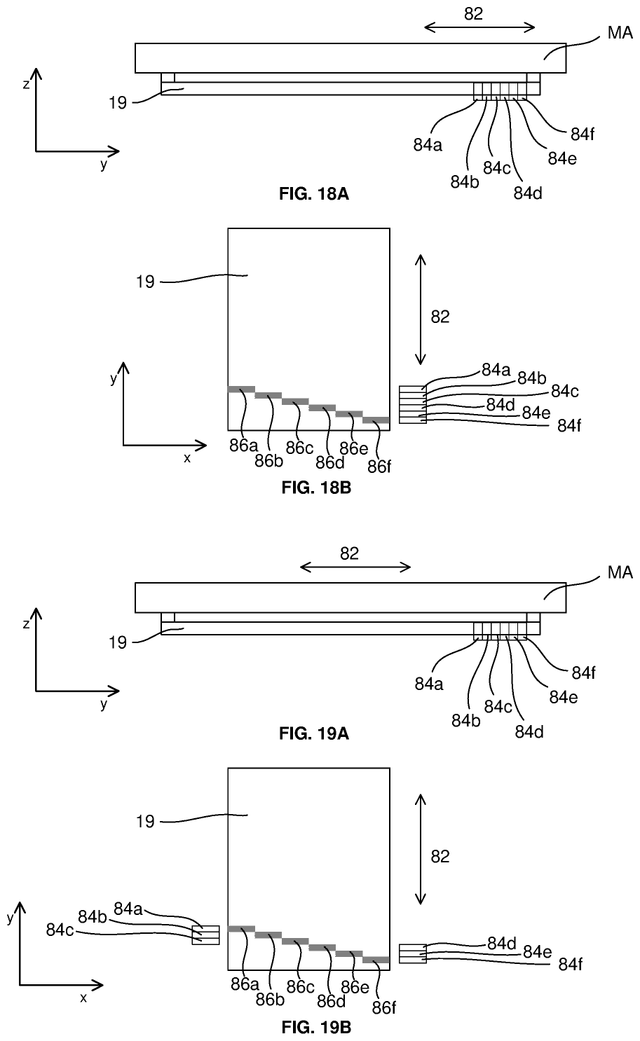

The embodiment shown in FIGS. 18A and 18B is the same as that shown in FIGS. 16A and 16B expect that, in FIGS. 18A and 18B, the source 84 comprises six individual radiation sources 86a-86f, each of which is operable to direct a portion 86a-86f of the radiation curtain 86 at the pellicle 19 such that it is incident on the pellicle 19 at a grazing incidence angle, with a direction of the radiation having a component in the non-scanning direction (i.e. the x-direction).

The embodiment shown in FIGS. 19A and 19B is the same as that shown in FIGS. 18A and 18B expect that, in FIGS. 19A and 19B, three of the individual radiation sources 86a-86c are disposed on one side of the pellicle 19 and the other three of the individual radiation sources 86d-86f are disposed on the other side of the pellicle 19.

In one embodiment, the heating system 20 is operable to use the EUV radiation beam B to heat the pellicle 19. In this case the x masking blades 32, 34 and the y masking blades 36, 38 are completely opened to extend the exposure field region 44 (see FIG. 4). This can only be done if there is no substrate W below the projection system PS (to prevent unwanted exposure of the substrate W) or if the EUV radiation is stopped by the projection system PS (for example, using a shutter in a dynamic gas lock of the projection system PS). This heating method (using EUV radiation) can be effective if the required time between CNT pellicle 19 cycle is larger than the exposure time of a single substrate W. In this case, the pellicle 19 can be exposed in between exposure of consecutive substrates W.

Some embodiments of the present disclosure relate to methods for using a reticle and pellicle assembly 15. The method may comprise: illuminating the reticle and pellicle assembly 15 with a radiation beam B so as to impart the radiation beam with a pattern in its cross-section and forming an image of the reticle MA on a substrate W; and heating the pellicle 19 of the reticle and pellicle assembly 15 using a separate heat source. The separate heat source may be the heating system 20 described above.

Some embodiments of the present disclosure relate to a pellicle 19 for use in a lithographic apparatus LA, the pellicle 19 comprising a substrate formed from carbon nanotubes; wherein the substrate further comprises at least one additive.

The at least one additive may comprises a plurality of catalyst atoms distributed over the substrate.

A concentration and type of the at least one additive may be such that a threshold temperature above which a hydrogen etching rate of the pellicle falls to a negligible level is less than 900 K. In some embodiments, a concentration and type of the at least one additive is such that a threshold temperature above which a hydrogen etching rate of the pellicle falls to a negligible level is less than 800 K. In some embodiments, a concentration and type of the at least one additive is such that a threshold temperature above which a hydrogen etching rate of the pellicle falls to a negligible level is less than 700 K. In some embodiments, a concentration and type of the at least one additive is such that a threshold temperature above which a hydrogen etching rate of the pellicle falls to a negligible level is less than 600 K.

In some embodiments, the at least one additive may comprise a transition metal. For example, the at least one additive may comprise: molybdenum, chromium, nickel, copper and/or iron. A concentration of the at least one additive with respect to carbon atoms is of the order of 0.1-2%. For example, a concentration of the at least one impurity with respect to carbon atoms may be of the order of 0.1-1%. It is expected that such a concentration of additives will not significantly decrease EUV transmissivity of the pellicle. For example, for a 1% concentration of molybdenum atoms it is estimated that EUV transmissivity of the pellicle will decrease by <0.1%. Similarly, for a 1% concentration of nickel atoms it is estimated that EUV transmissivity of the pellicle will decrease by <0.5%.

Additionally or alternatively, in some embodiments the at least one additive may comprise boron. For example, a concentration of boron with respect to carbon atoms may be of the order of 15 at. % (i.e. an atomic percentage of around 15%).

Additionally or alternatively, in some embodiments the at least one additive may comprise amorphous carbon.

References to a mask or reticle in this document may be interpreted as references to a patterning device (a mask or reticle is an example of a patterning device) and the terms may be used interchangeably. In particular, the term mask assembly is synonymous with reticle assembly and patterning device assembly.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use vacuum conditions or ambient (non-vacuum) conditions.

The term “EUV radiation” may be considered to encompass electromagnetic radiation having a wavelength within the range of 4-20 nm, for example within the range of 13-14 nm. EUV radiation may have a wavelength of less than 10 nm, for example within the range of 4-10 nm such as 6.7 nm or 6.8 nm.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A lithographic apparatus comprising:
an illumination system configured to condition a radiation beam;
a support structure constructed to support a reticle and pellicle assembly for receipt of the radiation beam conditioned by the illumination system;
a substrate table constructed to support a substrate;
a projection system configured to receive the radiation beam from the reticle and pellicle assembly and to project the radiation beam onto the substrate; and
a heating system configured to to heat a pellicle of the reticle and pellicle assembly supported by the support structure.

2. The lithographic apparatus of claim 1, further comprising a controller configured to control the heating system so as to heat a pellicle of the reticle and pellicle assembly supported by the support structure so as to achieve a target temperature distribution.

3. The lithographic apparatus of claim 1, wherein during exposure of the reticle and pellicle assembly supported by the support structure to radiation from the illumination system, the heating system is configured to maintain at least a portion of the pellicle of the reticle and pellicle assembly above a minimum temperature.

4. The lithographic apparatus of claim 3, wherein the minimum temperature is a temperature at which a hydrogen etching rate of the pellicle is negligible.

5. The lithographic apparatus of claim 3, wherein the minimum temperature is 800 K or above.

6. The lithographic apparatus of claim 1, wherein the heating system is configured to heat at least a portion of the pellicle surrounding the portion of the pellicle which is currently receiving the radiation beam.

7. The lithographic apparatus of claim 1, further comprising a support structure scanning mechanism operable to move the support structure relative to the radiation beam conditioned by the illumination system so as to move the reticle and pellicle assembly supported by the support structure through the radiation beam and wherein the heating system is configured to heat at least a portion of the pellicle which is currently receiving the radiation beam.

8. The lithographic apparatus of claim 7, wherein the heating system is also configured to heat at least a portion of the pellicle surrounding the portion of the pellicle which is currently receiving the radiation beam.

9. The lithographic apparatus of claim 1, wherein the heating system is configured so as to heat the pellicle of the reticle and pellicle assembly supported by the support structure so that a combined heat load from the heating system and the radiation beam received from the illumination system achieves a target temperature distribution.

10. The lithographic apparatus of claim 1, wherein the heating system is configured to heat substantially an entire membrane of the pellicle.

11. The lithographic apparatus of claim 1, wherein the heating system comprises a radiation source operable to direct radiation at the pellicle of the reticle and pellicle assembly when supported by the support structure.

12.-39. (canceled)

40. A method for using a reticle and pellicle assembly, the method comprising:
illuminating the reticle and pellicle assembly with a radiation beam so as to impart the radiation beam with a pattern in its cross-section and forming an image of the reticle on a substrate; and
heating the pellicle of the reticle and pellicle assembly using a separate heat source.

41. The method of claim 40, wherein the heating of the pellicle of the reticle and pellicle assembly using a separate heat source is such that the pellicle achieves a target temperature distribution.

42.-71. (canceled)

72. A pellicle for use in a lithographic apparatus, the pellicle comprising a substrate formed from carbon nanotubes, wherein the substrate further comprises at least one additive.

73. The pellicle of claim 72, wherein the at least one additive comprises a plurality of catalyst atoms distributed over the substrate.

74. The pellicle of claim 72, wherein a concentration of the at least one additive with respect to carbon atoms is of the order of 0.1-2%.

75. The pellicle of claim 72, wherein a concentration and type of the at least one additive is such that a threshold temperature above which a hydrogen etching rate of the pellicle is negligible is less than 900 K.

76. The pellicle of claim 72, wherein the at least one additive comprises a transition metal.

77. The pellicle of claim 72, wherein the at least one additive comprises: molybdenum, chromium, nickel, copper and/or iron.

78. The pellicle of claim 72, wherein the at least one additive comprises boron.

79.-80. (canceled)
